(19) United States
(12) Patent Application Publication
(10) Pub. No.: US 2026/0033092 A1
(43) Pub. Date: Jan. 29, 2026

(54) DISPLAY DEVICE AND TEST METHOD OF DISPLAY DEVICE

(71) Applicant: LG Display Co., Ltd., Seoul (KR)

(72) Inventors: Chan Woo IM, Paju-si (KR); Kyoung June JUNG, Paju-si (KR); Dae Han WON, Paju-si (KR); Jeen Wook KWON, Paju-si (KR)

(73) Assignee: LG Display Co., Ltd., Seoul (KR)

(21) Appl. No.: 19/252,550

(22) Filed: Jun. 27, 2025

(30) Foreign Application Priority Data
Jul. 23, 2024 (KR) 10-2024-0097300

(51) Int. Cl. H10H 29/80; H01L 21/66; H10H 29/01; H10H 29/37; H10H 29/49

(52) U.S. Cl. CPC H10H 29/8321; H01L 22/22; H10H 29/032; H10H 29/37; H10H 29/49

(57) ABSTRACT

A display device and a test method of the display device are discussed. The display device can include a substrate having a display region and a non-display region, a circuit layer disposed in the display region and the non-display region, a plurality of banks disposed on the circuit layer, and a plurality of pixels each including a plurality of light-emitting elements disposed on the plurality of banks in the display region. The first electrodes of the plurality of pixels are connected to the anode electrodes of the plurality of light-emitting elements, and the second electrodes of the plurality of pixels are connected to the cathode electrodes of the plurality of light-emitting elements. Adjacent second electrodes of the pixels are disposed to face each other and are spaced apart from each other.

### CROSS-REFERENCE TO RELATED APPLICATION

This application claims priority to and the benefit of Korean Patent Application No. 10-2024-0097300, filed in the Republic of Korea on Jul. 23, 2024, the disclosure of which is incorporated herein by reference in its entirety into the present application.

### BACKGROUND

### 1. Field of the Invention

The present disclosure relates to a display device and a test method of a display device.

### 2. Discussion of Related Art

Display devices include an organic light-emitting display (OLED) device which emits light by itself, a liquid crystal display (LCD) device which requires a separate light source, and the like.

Recently, display devices including inorganic light-emitting elements (light-emitting diodes, LEDs) are attracting attention as next generation display devices. The inorganic light-emitting elements are formed of an inorganic material rather than an organic material, and thus the display devices including inorganic light-emitting elements can have a faster lighting speed and higher luminous efficacy, and display higher brightness images compared to an LCD device or OLED device.

### SUMMARY OF THE DISCLOSURE

Embodiments of the present disclosure are directed to providing a display device capable of monitoring a cathode short circuit in advance through resistance measurement between adjacent cathode patterns when a cathode residual film occurs by adding a test element group (TEG) structure which is a test pattern in a dummy region, and a test method of the display device.

The objects according to embodiments of the present disclosure are not limited to the above-described objects, and other objects that are not mentioned will be clearly understood by those skilled in the art from the following description.

A display device according to an embodiment of the present disclosure includes: a substrate having a display region and a non-display region outside the display region; a circuit layer disposed in the display region and the non-display region; a plurality of banks disposed on the circuit layer; a plurality of pixels each including a plurality of light-emitting elements disposed on the plurality of banks in the display region, wherein first electrodes of the plurality of pixels are connected to anode electrodes of the plurality of light-emitting elements, and second electrodes of the plurality of pixels are connected to cathode electrodes of the plurality of light-emitting elements, and adjacent second electrodes are disposed to face each other and are spaced apart from each other; a plurality of dummy pixels each including a plurality of dummy light-emitting elements disposed on the plurality of banks in the non-display region, wherein a plurality of first dummy electrode lines of the plurality of dummy pixels are connected to anode electrodes of the plurality of dummy light-emitting elements and not connected to each other, and a plurality of second dummy electrodes of the plurality of dummy pixels are connected to cathode electrodes of the plurality of dummy light-emitting elements, adjacent second dummy electrodes are disposed to face each other and are spaced apart from each other.

Specific details according to the various examples of the present disclosure other than solutions to the above-mentioned problems are included in the description and drawings described below.

### BRIEF DESCRIPTION OF THE DRAWINGS

The following drawings attached to this specification illustrate embodiments of the present disclosure and, together with the detailed description of the invention to be described below, serve to further understand the technical ideas and advantages of the present invention, and therefore the present invention should not be construed as being limited to matters described in such drawings, in which:

FIG. 1 is an exploded perspective view of a display device according to embodiments of the present disclosure;

FIG. 2 is a plan view of the display device according to the embodiments of the present disclosure;

FIG. 3 is an enlarged partial plan view of a connection structure of the display device according to the embodiments of the present disclosure;

FIG. 4 is a view showing a circuit structure in the display device according to the embodiments of the present disclosure;

FIG. 5 is a partial plan view of the display device according to the embodiments of the present disclosure;

FIG. 6 is a partial plan view of the display device according to the embodiments of the present disclosure;

FIG. 7 is a cross-sectional view of a display panel of the display device according to the embodiments of the present disclosure;

FIG. 8 is an enlarged cross-sectional view of a subpixel of the display device according to the embodiments of the present disclosure;

FIG. 9 is a plan view of a display panel of the display device according to the embodiments of the present disclosure;

FIG. 10 is an enlarged partial plan view of the display device according to the embodiments of the present disclosure;

FIG. 11 is a cross-sectional view taken along line I-I′ in FIG. 10;

FIG. 12 is a cross-sectional view taken along line II-II′ in FIG. 10;

FIG. 13 is an enlarged plan view of a test element group (TEG) structure of a dummy region in the display device according to the embodiments of the present disclosure;

FIG. 14 is an enlarged plan view of portion C in FIG. 13;

FIG. 15 is a cross-sectional view taken along line III-III′ in FIG. 14;

FIG. 16 is a cross-sectional view taken along line IV-IV′ in FIG. 14; and

FIGS. 17 to 20 are views showing devices to which the display devices according to the embodiments of the present disclosure are applied.

### DETAILED DESCRIPTION OF THE EMBODIMENTS

Advantages and features of the present disclosure and methods of achieving them will become apparent with reference to the following embodiments, which are described in detail, in conjunction with the accompanying drawings. However, the present disclosure is not limited to the embodiments to be described below and can be implemented in various different forms, the embodiments are only provided to completely disclose the present disclosure and completely convey the scope of the present disclosure to those skilled in the art.

Since the shapes, sizes, proportions, angles, numbers, and the like disclosed in the drawings for describing the embodiments of the present disclosure are only exemplary, the present disclosure is not limited to the items shown in the drawings. The same reference numbers indicate the same components throughout the disclosure. Further, in describing the present disclosure, when it is determined that a detailed description of related known technology can unnecessarily obscure the gist of the present disclosure, the detailed description thereof will be omitted. When “providing,” “including,” “having,” “consisting of,” and the like are used herein, other parts can be added unless ‘only’ is used. A case in which a component is expressed in a singular form can include a plural form unless explicitly stated otherwise.

In interpreting a component, the component is interpreted as including a margin of error even when there is no separate explicit description of the margin of error.

In a description of a positional relationship, when the positional relationship of two parts such as “on,” “at an upper portion,” “at a lower portion,” “next to,” “adjacent to,” or the like is described, one or more other parts can be located between two components unless “immediately,” “directly,” “close to” is used.

In a description of a temporal relationship, when the temporal relationship is described as “after,” “following,” “and then,” “before,” or the like, non-consecutive cases can also be included unless “immediately” or “directly” is used.

Although first, second, and the like are used to describe various components, these components are not limited by these terms. These terms are only used to distinguish one component from another component and may not define order or sequence. Accordingly, a first component described below can also be a second component within the technical spirit of the present disclosure.

Terms, such as first, second, A, B, (a), and (b) can be used to describe components of the present disclosure. These terms are only for the purpose of distinguishing one component from another component, and the nature, sequence, order, or the like of the corresponding components is not limited by these terms.

When a component is described as being “connected,” “coupled,” “linked,” or “attached” to another component, it should be understood that the component can be directly connected, coupled, linked, or attached to the other component, but another component can be interposed between the components which can be indirectly connected, coupled, linked, or attached to each other unless explicitly stated otherwise.

When a component or layer is described as being “in contact with” or “overlapping” another component or layer, it should be understood that the component or layer can be in direct contact with or directly overlap another component or layer, but another component can be interposed between the components which can be in direct contact with or directly overlap each other unless explicitly stated otherwise.

“At least one” should be understood as including a combination of one or more of the related components. For example, the term “at least one of first, second, and third components” includes not only the first, second, or third component, but also all combinations of two or more of the first, second, and third components.

The terms “first direction,” “second direction,” “third direction,” “X-axis direction,” “Y-axis direction,” and “Z-axis direction” should not be understood as only a geometric relationship in which relationships therebetween are perpendicular to each other, but mean that a configuration of the present disclosure has a broader directionality within a range in which it can functionally act. Further, the term “can” fully encompasses all the meanings and coverages of the term “may” and vice versa.

Features of various embodiments of the present disclosure can be partially or entirely combined with each other, and technically, various interconnections and operations are possible, and the embodiments can be implemented independently of each other or together in a related relationship.

A display panel of the present disclosure can include dummy pixels which can be in contact with test element group (TEG) test equipment. The dummy pixels have substantially the same structure as pixels in a display region and thus can be used as dummy elements capable of indirectly measuring whether a short circuit defect occurs in the pixels. The dummy pixels can be disposed in a non-display region outside the display region. The TEG test equipment can be in contact with lines extending from the dummy pixels to measure electrical characteristics of transistors in the dummy pixels such as resistance (R), capacitance (C), and the like.

Hereinafter, various embodiments of the present disclosure will be described in detail with reference to the accompanying drawings. All the components of each display device/apparatus according to all embodiments of the present disclosure are operatively coupled and configured.

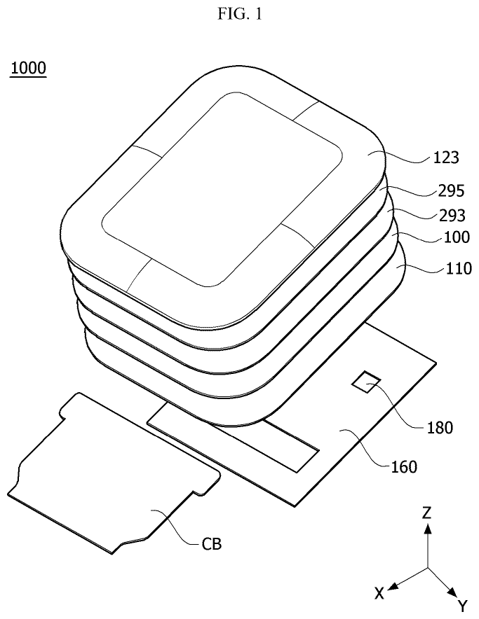

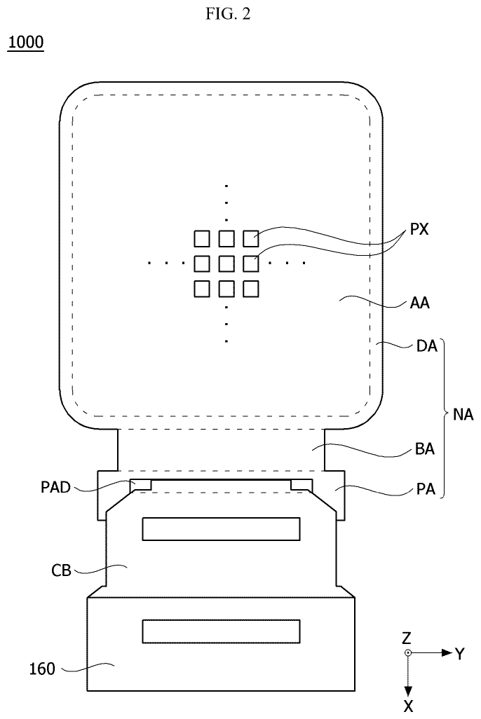

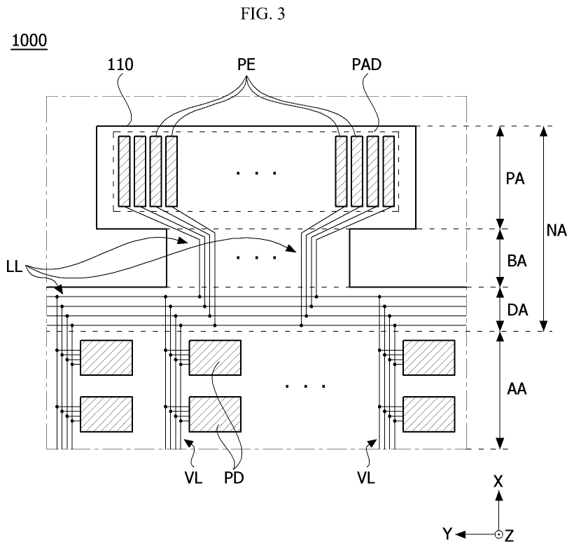

FIG. 1 is an exploded perspective view of a display device according to embodiments of the present disclosure. FIG. 2 is a plan view of the display device according to the embodiments of the present disclosure. FIG. 3 is an enlarged partial plan view of a connection structure of the display device according to the embodiments of the present disclosure.

Referring to FIGS. 1 to 3, a display device 1000 according to the embodiments of the present disclosure can include a display panel 100, a polarization layer 293, a cover adhesive layer 295, a cover member 123, a substrate 110, a flexible circuit board CB, and a printed circuit board 160.

For example, the display device 1000 can include the substrate 110. The substrate 110 can be a member which supports other components of the display device 1000. The substrate 110 can be formed of an insulating material. For example, the substrate 110 can be formed of glass, a resin, or the like. Further, the substrate 110 can be formed of a material having flexibility. For example, the substrate 110 can be formed of a plastic material having flexibility such as polyimide (PI) or the like. However, the embodiments of the present disclosure are not limited thereto.

The display panel 100 can implement information, a video, and/or an image provided to a user. For example, the display panel 100 can include a display region AA (or active area) and a non-display region NA (or non-active area). For example, the substrate 110 can include the display region AA and the non-display region NA. The display region AA and the non-display region NA are not limited to the substrate 110, but can be provided throughout the display device 1000.

The display region AA can be a region where an image is displayed. The display region AA can include a plurality of pixels PX. Each of the plurality of pixels PX can be composed of a plurality of subpixels. A plurality of light-emitting elements can be disposed in each of the plurality of subpixels. The plurality of light-emitting elements can be configured differently depending on the type of display device 1000. For example, when the display device 1000 is an inorganic light-emitting display device, the light-emitting element can be a light-emitting diode (LED), a micro light-emitting diode (micro LED), or a mini light-emitting diode (mini LED), but the embodiments of the present disclosure are not limited thereto.

The non-display region NA can be a region where an image is not displayed. Various lines and circuits for driving the plurality of pixels PX of the display region AA can be disposed in the non-display region NA. For example, in the non-display region NA, various lines and driving circuits can be mounted, and a pad portion PAD to which an integrated circuit, a printed circuit, and the like are connected can be disposed, but the embodiments of the present disclosure are not limited thereto.

For example, the driving circuit can be a data driving circuit and/or a gate driving circuit, but the embodiments of the present disclosure are not limited thereto. Lines through which control signals for controlling the driving circuits are supplied can be disposed on the display panel 100. For example, the control signals can include various timing signals including a clock signal, an input data enable signal, and a synchronization signal, but the embodiments of the present disclosure are not limited thereto. The control signals can be received through the pad portion PAD. For example, link lines LL for transmitting signals can be disposed in the non-display region NA. For example, driving components such as the flexible circuit board CB and the printed circuit board 160 can be connected to the pad portion PAD.

According to the present disclosure, the non-display region NA can include a dummy region DA, a bending region BA, and a pad region PA. For example, the dummy region DA can be a region surrounding at least a portion of the display region AA. The bending region BA is a region extending from at least one side of a plurality of sides of the dummy region DA, and can be a bendable region. The pad region PA is a region extending from the bending region BA, and the pad portion PAD can be disposed therein. For example, the bending region BA can be in a bent state, and the remaining region of the substrate 110 excluding the bending region BA can be in a flat state. In this case, as the bending region BA is bent, the pad region PA can be located on a rear surface of the display region AA. However, the embodiments of the present disclosure are not limited thereto.

The display region AA can be configured in various shapes depending on the design of the display device 1000. For example, the display region AA can be configured in a rectangular shape whose four corners are formed in a round shape, but the embodiments of the present disclosure are not limited thereto. For another example, the display region AA can be configured in a rectangular shape whose four corners are formed in a right-angled shape, a circular shape, or the like, but the embodiments of the present disclosure are not limited thereto.

According to the present disclosure, a width of the pad region PA where a plurality of pad electrodes PE are disposed can be wider than a width of the bending region BA where only a plurality of link lines LL are disposed. Further, a width of the display region AA where the plurality of subpixels are disposed can be wider than the width of the bending region BA where only the plurality of link lines LL are disposed. The drawings show that the width of the bending region BA is narrower than widths of other regions of the substrate 110, but the shape of the substrate 110 including the bending region BA is exemplary, and the embodiments of the present disclosure are not limited thereto.

Referring to FIG. 2, in the display device according to the embodiments of the present disclosure, the display region AA where the plurality of pixels PX are disposed and the dummy region DA surrounding the display region AA can be disposed.

Referring to FIG. 3, a plurality of pixel driving circuits PD can be disposed in the display region AA. The plurality of pixel driving circuits PD can be circuits for driving the light-emitting elements of the plurality of subpixels. Each of the plurality of pixel driving circuits PD includes a plurality of transistors including a driving transistor, a storage capacitor, and the like and can control the light-emitting operations of the plurality of light-emitting elements by supplying control signals, power, and driving current to the light-emitting elements of the plurality of subpixels. For example, the pixel driving circuit PD can include a power line and a signal line for controlling the emission on/off and/or emission time of the light-emitting elements. For example, the plurality of pixel driving circuits PD can be drivers manufactured using a metal-oxide-silicon field effect transistor (MOSFET) manufacturing process on a semiconductor substrate, but the embodiments of the present disclosure are not limited thereto. The driver can include the plurality of pixel driving circuits PD and can drive the plurality of subpixels.

Referring together to FIG. 1, the flexible circuit board CB and the printed circuit board 160 can be disposed under the display panel 100. The flexible circuit board CB and the printed circuit board 160 can be disposed at least on an edge of one side of the display panel 100, but the embodiments of the present disclosure are not limited thereto. One side of the flexible circuit board CB can be attached to the display panel 100 and the other side can be attached to the printed circuit board 160, but the embodiments of the present disclosure are not limited thereto. The flexible circuit board CB can be a flexible film, but the embodiments of the present disclosure are not limited thereto.

The pad portion PAD including a plurality of pad electrodes PE can be disposed in the pad region PA. Driving components including one or more flexible circuit boards (or flexible films) CB and the printed circuit board 160 can be attached or bonded to the pad portion PAD. The plurality of pad electrodes PE of the pad portion PAD are electrically connected to one or more flexible circuit boards (or flexible films) CB by a conductive adhesive layer ACF, and various signals (or power) from the printed circuit board 160 and the flexible circuit boards (or flexible films) CB can be transmitted to the plurality of pixel driving circuits PD of the display region AA.

The flexible circuit board (or flexible film) CB can be a film in which various components are disposed on a flexible base film. For example, a driving integrated circuit (IC) such as a gate driver IC or a data driver IC can be disposed on the flexible circuit board (or flexible film) CB, but the embodiments of the present disclosure are not limited thereto. The driving IC can be a component which processes data and sends a driving signal for displaying an image. The driving IC can be disposed in a manner such as a chip on glass (COG), a chip on film (COF), a tape carrier package (TCP), or the like depending on a mounting method, but the embodiments of the present disclosure are not limited thereto. The flexible circuit board (or flexible film) CB can be attached or bonded to the plurality of pad electrodes PE through a conductive adhesive layer, but the embodiments of the present disclosure are not limited thereto.

The printed circuit board 160 be a component which is electrically connected to one or more flexible circuit boards (or flexible films) CB and supplies a signal to the driving IC. The printed circuit board 160 can be disposed on one side of the flexible circuit board (or flexible film) CB and can be electrically connected to the flexible circuit board (or flexible film) CB. Various components for supplying various signals to the driving IC can be disposed on the printed circuit board 160. For example, various components such as a timing controller, a power supply, a memory, a processor, and the like can be disposed on the printed circuit board 160. For example, the printed circuit board 160 can include a power management integrated circuit (PMIC), but the embodiments of the present disclosure are not limited thereto.

The printed circuit board 160 can include at least one hole 180, but the embodiments of the present disclosure are not limited thereto. An internal component which detects ambient light, temperature, or the like, which can be provided to a plurality of sensors, can be disposed in a region corresponding to the at least one hole 180. For example, the internal component can include an ambient light sensor (ALS) or a temperature sensor, but the embodiments of the present disclosure are not limited thereto. For example, the hole 180 can be a through hole or the like, but the embodiments of the present disclosure are not limited thereto.

Referring to FIG. 1, the polarization layer 293 can be disposed on the display panel 100. The polarization layer 293 can prevent or reduce the light generated from an external light source from entering the display panel 100 and affecting the light-emitting element or the like.

The cover member 123 can be disposed on the polarization layer 293. The cover member 123 can be a member for protecting the display panel 100. The cover adhesive layer 295 can be disposed between the polarization layer 293 and the cover member 123. The cover member 123 can be attached to the display panel 100 by the cover adhesive layer 295. The cover adhesive layer 295 can include an optically clear adhesive (OCA), an optically clear resin (OCR), a pressure sensitive adhesive (PSA), or the like, but the embodiments of the present disclosure are not limited thereto.

The substrate 110 can be disposed between the display panel 100 and the printed circuit board 160. The substrate 110 can reinforce the rigidity of the display panel 100. The substrate 110 can be a back plate, but the embodiments of the present disclosure are not limited thereto.

Referring to FIGS. 1 to 3, the plurality of link lines LL can be disposed in the dummy region DA and the pad region PA. The plurality of link lines LL can be lines which transmit various signals from one or more flexible circuit boards (or flexible films) CB and the printed circuit board 160 to the display region AA. The plurality of link lines LL can extend from the plurality of pad electrodes PE of the pad region PA toward the bending region BA and the dummy region DA and can be electrically connected to a plurality of driving lines VL of the display region AA. The plurality of pixel driving circuits PD can be driven by receiving signals from one or more flexible circuit boards (or flexible films) CB and the printed circuit board 160 through the driving lines VL of the display region AA and the link lines LL of the non-display region NA.

For example, the plurality of driving lines VL can be lines for transmitting the signals output from the flexible circuit boards (or flexible films) CB and the printed circuit board 160 to the plurality of pixel driving circuits PD along with the plurality of link lines LL. The plurality of driving lines VL can be disposed in the display region AA and can be electrically connected to the plurality of pixel driving circuits PD. The plurality of driving lines VL can extend from the display region AA toward the non-display region NA and can be electrically connected to the plurality of link lines LL. Accordingly, the signals output from the flexible circuit boards (or flexible films) CB and the printed circuit board 160 can be respectively transmitted to the plurality of pixel driving circuits PD through the plurality of link lines LL and the plurality of driving lines VL.

As the bending region BA is bent, portions of the plurality of link lines LL can also be bent along with the bending region BA. Stress can be concentrated on portions of the bent link lines LL, and accordingly, cracks can occur in the link lines LL. Accordingly, the plurality of link lines LL can be composed of a conductive material having excellent flexibility to reduce cracks when the bending region BA is bent. For example, the plurality of link lines LL can be composed of a conductive material having excellent flexibility such as gold (Au), silver (Ag), aluminum (Al), or the like, but the embodiments of the present disclosure are not limited thereto.

Further, the plurality of link lines LL can be composed of one of various conductive materials used in the display region AA. For example, the plurality of link lines LL can be composed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto. The plurality of link lines LL can be formed in a multi-layer structure including various conductive materials.

For example, the plurality of link lines LL can be configured in a triple-layer structure of titanium (Ti)/aluminum (Al)/titanium (Ti), but the embodiments of the present disclosure are not limited thereto.

The plurality of link lines LL can be configured in various shapes to reduce stress.

At least portions of the plurality of link lines LL disposed in the bending region BA can extend in the same direction as an extending direction of the bending region BA, or can extend in a different direction from the extending direction of the bending region BA to reduce stress. For example, when the bending region BA extends in one direction from the dummy region DA toward the pad region PA, at least portions of the link lines LL disposed in the bending region BA can extend in a direction oblique to the one direction.

For another example, at least portions of the plurality of link lines LL can be configured in various pattern shapes. For example, at least portions of the plurality of link lines LL disposed in the bending region BA can have a shape in which a conductive pattern having at least one of a diamond shape, a rhombus shape, a trapezoidal wave shape, a triangular wave shape, a sawtooth wave shape, a sine wave shape, a circular shape, and an omega (52) shape is repeatedly disposed, but the embodiments of the present disclosure are not limited thereto.

Accordingly, in order to minimize the stress concentrated on the plurality of link lines LL and cracks resulting from the stress, the plurality of link lines LL can be formed in various shapes including the above-described shapes, but the embodiments of the present disclosure are not limited thereto.

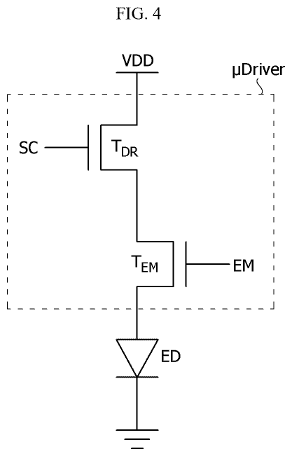

FIG. 4 is a view showing a circuit structure in the display device according to the embodiments of the present disclosure.

In FIG. 4, an example in which one light-emitting element ED is connected to a micro driver μDriver is shown, but the present disclosure is not limited thereto. For example, 8 light-emitting elements ED can be connected to one micro driver μDriver. For another example, 16 light-emitting elements ED can be connected to one micro driver μDriver, or 32 light-emitting elements ED or 64 light-emitting elements ED can be simultaneously connected to one micro driver μDriver. The light-emitting element ED can be a micro inorganic light-emitting element (μLED). However, the present disclosure is not limited thereto.

One micro driver μDriver can include a driving transistor T_{DR} and a light-emitting transistor T_{EM}, but embodiments herein are not limited thereto. For example, in the driving transistor T_{DR}, a high potential power voltage VDD can be applied to a first electrode, a first electrode of the light-emitting transistor T_{EM} can be connected to a second electrode, and a scan signal SC can be applied to a gate electrode. The scan signal SC applied to the gate electrode of the driving transistor T_{DR} is direct current power, and a fixed reference voltage Vref can be applied for each frame, but the embodiments of the present disclosure are not limited thereto.

In the light-emitting transistor T_{EM}, the second electrode of the driving transistor T_{DR} can be connected to the first electrode, the light-emitting element ED can be connected to a second electrode, and an emission signal EM can be applied to a gate electrode. The emission signal EM applied to the gate electrode of the light-emitting transistor T_{EM} can be a pulse width modulation signal which varies for each frame, but the embodiments of the present disclosure are not limited thereto.

A first electrode of the light-emitting element ED can be connected to the second electrode of the light-emitting transistor T_{EM}, and a second electrode of the light-emitting element ED can be connected to the ground. For example, the first electrode of the light-emitting element ED can be an anode electrode and the second electrode of the light-emitting element ED can be a cathode electrode, but the embodiments of the present disclosure are not limited thereto.

The driving transistor T_{DR} and the light-emitting transistor T_{EM} can each be an n-type transistor or a p-type transistor.

In the micro driver μDriver, the driving transistor T_{DR} can be turned on by the scan signal SC applied from a timing controller (T-CON), and the light-emitting transistor T_{EM} can be turned on by the emission signal EM. Accordingly, as a driving current is applied to the light-emitting element ED via the driving transistor T_{DR} and the light-emitting transistor T_{EM} by the high potential power voltage VDD applied to the first electrode of the driving transistor T_{DR}, the light-emitting element ED can emit light.

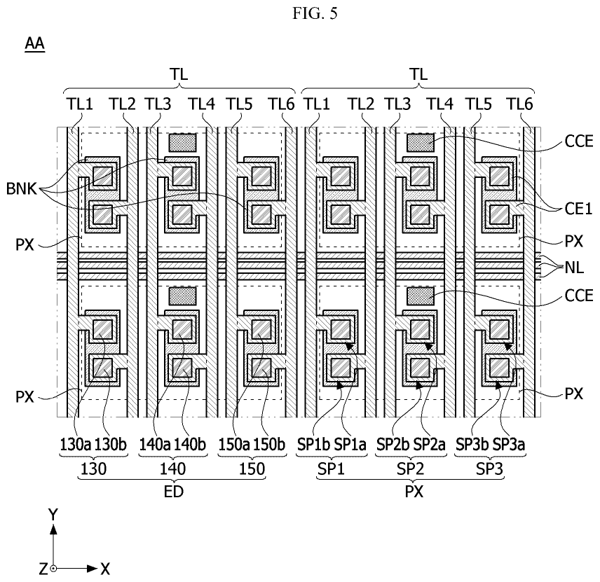

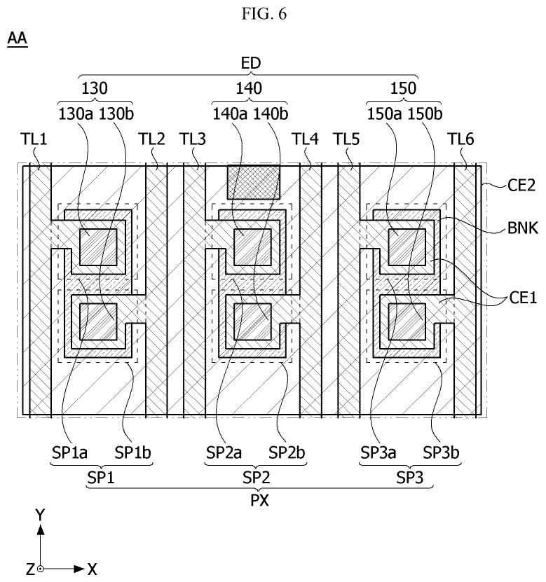

FIGS. 5 and 6 are partial plan views of the display device according to the embodiments of the present disclosure. For example, FIG. 5 is an enlarged partial plan view of the display region including the plurality of pixels. For example, FIG. 6 is an enlarged partial plan view of the display region including one pixel.

In FIG. 5, a plurality of signal lines TL, a plurality of communication lines NL, a plurality of first electrodes CE1, a plurality of banks BNK, and a plurality of light-emitting elements ED are shown, but the embodiments of the present disclosure are not limited thereto. FIG. 6 is an enlarged partial plan view of the display region in which a second electrode CE2 is additionally disposed compared with FIG. 5. A plurality of second electrodes CE2 can be additionally disposed in the display region of FIG. 5.

Referring to FIG. 5, the plurality of pixels PX, each composed of a plurality of subpixels can be disposed in the display region AA. Each of the plurality of subpixels includes a light-emitting element ED and can independently emit light. The plurality of subpixels can be disposed in a matrix form, forming a plurality of rows and a plurality of columns, but the embodiments of the present disclosure are not limited thereto.

The plurality of subpixels can include a first subpixel SP1, a second subpixel SP2, and a third subpixel SP3. For example, one of the first subpixel SP1, the second subpixel SP2, and the third subpixel SP3 can be a red subpixel, another can be a green subpixel, and the remaining one can be a blue subpixel. The types of the plurality of subpixels are exemplary, and the embodiments of the present disclosure are not limited thereto.

Each of the plurality of pixels PX can include one or more first subpixels SP1, one or more second subpixels SP2, and one or more third subpixels SP3. For example, one pixel PX can include a pair of first subpixels SP1, a pair of second subpixels SP2, and a pair of third subpixels SP3. The pair of first subpixels SP1 can be composed of a 1-1 subpixel SP1a and a 1-2 subpixel SP1b. The pair of second subpixels SP2 can be composed of a 2-1 subpixel SP2a and a 2-2 subpixel SP2b.

The pair of third subpixels SP3 can be composed of a 3-1 subpixel SP3a and a 3-2 subpixel SP3b. For example, one pixel PX can include the 1-1 subpixel SP1a and the 1-2 subpixel SP1b, the 2-1 subpixel SP2a and the 2-2 subpixel SP2b, and the 3-1 subpixel SP3a and the 3-2 subpixel SP3b, but the embodiments of the present disclosure are not limited thereto.

The plurality of subpixels forming one pixel PX can be arranged in various ways. For example, in one pixel PX, the pair of first subpixels SP1 can be disposed in the same column, the pair of second subpixels SP2 can be disposed in the same column, and the pair of third subpixels SP3 can be disposed in the same column. The first subpixel SP1, the second subpixel SP2, and the third subpixel SP3 can be disposed in the same row. The number and arrangement of the plurality of subpixels forming one pixel PX are exemplary, and the embodiments of the present disclosure are not limited thereto.

The plurality of signal lines TL can be disposed in regions between the plurality of subpixels. The plurality of signal lines TL can extend between the plurality of subpixels in a column direction. The plurality of signal lines TL can be lines which transmit an anode voltage from the pixel driving circuit PD to the plurality of subpixels. For example, the plurality of signal lines TL can be electrically connected to the plurality of pixel driving circuits PD and the first electrodes CE1 of the plurality of subpixels.

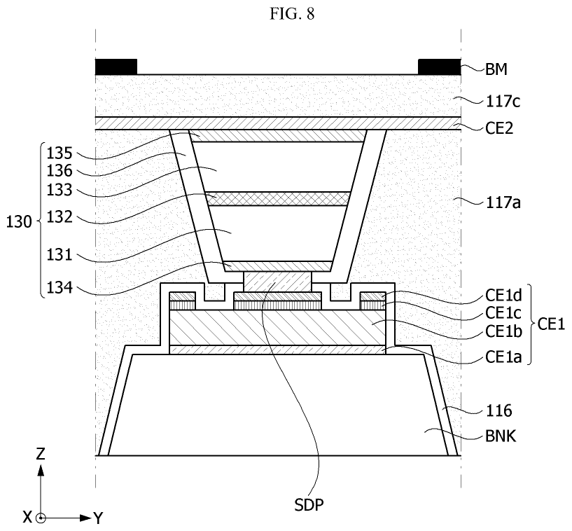

The anode voltage output from the pixel driving circuit PD can be transmitted to the first electrodes CE1 of the plurality of subpixels through the plurality of signal lines TL. For example, the first electrode CE1 can be an electrode electrically connected to an anode electrode 134 (FIG. 8) of the light-emitting element ED. Accordingly, the anode voltage from the signal line TL can be transmitted to the anode electrode 134 of the light-emitting element ED through the first electrode CE1.

Accordingly, instead of forming a plurality of transistors and a plurality of storage capacitors in each of the plurality of subpixels, a structure of the display device 1000 can be simplified using a pixel driving circuit PD in which a plurality of pixel circuits are integrated. Further, as the circuits disposed in each of the plurality of subpixels in conventional display devices are integrated into one pixel driving circuit PD, high efficiency and low power driving can be possible.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to the pair of first subpixels SP1, respectively. The third signal line TL3 and the fourth signal line TL4 can be electrically connected to the pair of second subpixels SP2, respectively. The fifth signal line TL5 and the sixth signal line TL6 can be electrically connected to the pair of third subpixels SP3, respectively.

The first signal line TL1 can be disposed on one side of the pair of first subpixels SP1, and the second signal line TL2 can be disposed on the other side of the pair of first subpixels SP1. The first signal line TL1 can be electrically connected to the first electrode CE1 of one of the pair of first subpixels SP1, for example, the 1-1 subpixel SP1a. The second signal line TL2 can be electrically connected to the first electrode CE1 of the other of the pair of first subpixels SP1, for example, the 1-2 subpixel SP1b.

The third signal line TL3 can be disposed on one side of the pair of second subpixels SP2, and the fourth signal line TL4 can be disposed on the other side of the pair of second subpixels SP2. For example, the third signal line TL3 can be disposed adjacent to the second signal line TL2. The third signal line TL3 can be electrically connected to the first electrode CE1 of one of the pair of second subpixels SP2, for example, the 2-1 subpixel SP2a. The fourth signal line TL4 can be electrically connected to the first electrode CE1 of the other of the pair of second subpixels SP2, for example, the 2-2 subpixel SP2b.

The fifth signal line TL5 can be disposed on one side of the pair of third subpixels SP3, and the sixth signal line TL6 can be disposed on the other side of the pair of third subpixels SP3. For example, the fifth signal line TL5 can be disposed adjacent to the fourth signal line TL4. The sixth signal line TL6 can be disposed adjacent to the first signal line TL1 connected to the neighboring pixel PX. The fifth signal line TL5 can be electrically connected to the first electrode CE1 of one of the pair of third subpixels SP3, for example, the 3-1 subpixel SP3a. The sixth signal line TL6 can be electrically connected to the first electrode CE1 of the other of the pair of third subpixels SP3, for example, the 3-2 subpixel SP3b.

The plurality of signal lines TL can be formed of a conductive material. For example, the plurality of signal lines TL can be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present disclosure are not limited thereto. For another example, the plurality of signal lines TL can be formed in a multi-layer structure of conductive materials. For example, the plurality of signal lines TL can be formed in a multi-layer structure of titanium (Ti)/aluminum (Al)/titanium (Ti)/indium tin oxide (ITO), but the embodiments of the present disclosure are not limited thereto.

The plurality of communication lines NL can be disposed in regions between the plurality of pixels PX. The plurality of communication lines NL can be disposed to extend in a row direction in the regions between the plurality of pixels PX. The plurality of communication lines NL can be disposed in regions between the plurality of second electrodes CE2 and may not overlap the plurality of second electrodes CE2. For example, the plurality of communication lines NL can be lines used for short-range communication such as near field communication (NFC). The plurality of communication lines NL can function as antennas. For example, the plurality of communication lines NL can be a plurality of connection lines, and the like, but the embodiments of the present disclosure are not limited thereto.

According to the present disclosure, a bank BNK can be disposed in each of the plurality of subpixels. The plurality of banks BNK can be structures on which the plurality of light-emitting elements ED are seated. The plurality of banks BNK can guide the positions of the plurality of light-emitting elements ED in a transfer process of transferring the plurality of light-emitting elements ED to the display device 1000. In the transfer process of the plurality of light-emitting elements ED, the plurality of light-emitting elements ED can be transferred onto the plurality of banks BNK. The plurality of banks BNK can be bank patterns or structures, or the like, but the embodiments of the present disclosure are not limited thereto.

Referring to FIGS. 5 and 6, a bank BNK of the first subpixel SP1, a bank BNK of the second subpixel SP2, and a bank BNK of the third subpixel SP3 can disposed spaced apart from each other. The bank BNK of the first subpixel SP1, the bank BNK of the second subpixel SP2, and the bank BNK of the third subpixel SP3 can be configured to be separated. Accordingly, the banks BNK of the first subpixel SP1, the second subpixel SP2, and the third subpixel SP3 to which different types of light-emitting elements ED are transferred can be easily identified.

A bank BNK of the 1-1 subpixel SP1a and a bank BNK of the 1-2 subpixel SP1b can be connected to each other or can be formed to be spaced apart or separated from each other. For example, in consideration of the design of the transfer process requirements or the like, the bank BNK of the 1-1 subpixel SP1a and the bank BNK of the 1-2 subpixel SP1b where the same type of light-emitting elements ED are disposed can be connected to each other or can be spaced apart or separated from each other. Further, a bank BNK of the 2-1 subpixel SP2a and a bank BNK of the 2-2 subpixel SP2b can be connected to each other or can be formed to be spaced apart or separated from each other. A bank BNK of the 3-1 subpixel SP3a and a bank BNK of the 3-2 subpixel SP3b can be connected to each other, or can be formed to be spaced apart or separated from each other. The embodiments of the present disclosure are not limited thereto

For example, the plurality of banks BNK can be formed of an organic insulating material. The plurality of banks BNK can be composed of a single layer or multiple layers of an organic insulating material. For example, the plurality of banks BNK can be composed of a photoresist, a polyimide (PI)-based material, an acryl-based material, or the like, but the embodiments of the present disclosure are not limited thereto.

The first electrode CE1 can be disposed in each of the plurality of subpixels. The first electrode CE1 can be disposed on the bank BNK. The first electrode CE1 can be electrically connected to one of the plurality of signal lines TL. At least a portion of the first electrode CE1 can extend outside the bank BNK and can be electrically connected to the signal line TL most adjacent to the first electrode CE1. For example, a portion of the first electrode CE1 of the 1-1 subpixel SP1a can extend to one side region of the 1-1 subpixel SP1a and can be electrically connected to the first signal line TL1, and a portion of the first electrode CE1 of the 1-2 subpixel SP1b can extend to the other side region of the 1-2 subpixel SP1b and can be electrically connected to the second signal line TL2. A portion of the first electrode CE1 of the 2-1 subpixel SP2a can extend to one side region of the 2-1 subpixel SP2a and can be electrically connected to the third signal line TL3, and a portion of the first electrode CE1 of the 2-2 subpixel SP2b can extend to the other side region of the 2-2 subpixel SP2b and can be electrically connected to the fourth signal line TL4. A portion of the first electrode CE1 of the 3-1 subpixel SP3a can extend to one side region of the 3-1 subpixel SP3a and can be electrically connected to the fifth signal line TL5, and a portion of the first electrode CE1 of the 3-2 subpixel SP3b can extend to the other side region of the 3-2 subpixel SP3b and can be electrically connected to the sixth signal line TL6.

The first electrode CE1 can be electrically connected to the anode electrode 134 of the light-emitting element ED and can transmit the anode voltage from the pixel driving circuit PD to the light-emitting element ED through the signal line TL. Different voltages can be applied to the first electrode CE1 of each of the plurality of subpixels depending on the image to be displayed. For example, different voltages can be applied to the first electrode CE1 of each of the plurality of subpixels. Accordingly, the first electrode CE1 can be a pixel electrode, but the embodiments of the present disclosure are not limited thereto.

The first electrode CE1 can be composed of a conductive material. For example, the first electrode CE1 can be integrally configured with the plurality of signal lines TL. For example, the first electrode CE1 can be composed of the same conductive material as the plurality of signal lines TL, but the embodiments of the present disclosure are not limited thereto. For example, the first electrode CE1 can be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present disclosure are not limited thereto. For another example, the first electrode CE1 can be formed in a multi-layer structure of conductive materials. For example, the plurality of first electrodes CE1 can be formed in a multi-layer structure of titanium (Ti)/aluminum (Al)/titanium (Ti)/indium tin oxide (ITO), but the embodiments of the present disclosure are not limited thereto.

The light-emitting element ED can be disposed in each of the plurality of subpixels. Each of the plurality of light-emitting elements ED can be any one of an LED and a micro LED, but the embodiments of the present disclosure are not limited thereto. The plurality of light-emitting elements ED can be disposed on the banks BNK and the first electrodes CE1. The plurality of light-emitting elements ED can be disposed on the first electrodes CE1 and can be electrically connected to the first electrodes CE1. Accordingly, the light-emitting element ED can emit light by receiving the anode voltage from the pixel driving circuit PD through the signal line TL and the first electrode CE1.

The plurality of light-emitting elements ED can include a first light-emitting element 130, a second light-emitting element 140, and a third light-emitting element 150. The first light-emitting element 130 can be disposed in the first subpixel SP1. The second light-emitting element 140 can be disposed in the second subpixel SP2. The third light-emitting element 150 can be disposed in the third subpixel SP3. For example, one of the first light-emitting element 130, the second light-emitting element 140, and the third light-emitting element 150 can be a red light-emitting element, another can be a green light-emitting element, and the remaining one can be a blue light-emitting element, but the embodiments of the present disclosure are not limited thereto. Accordingly, various colors of light including white can be implemented by combining red light, green light, and blue light emitted from the plurality of light-emitting elements ED. The types of the plurality of light-emitting elements ED are exemplary, and the embodiments of the present disclosure are not limited thereto.

The first light-emitting element 130 can include a 1-1 light-emitting element 130a disposed in the 1-1 subpixel SP1a and a 1-2 light-emitting element 130b disposed in the 1-2 subpixel SP1b. The second light-emitting element 140 can include a 2-1 light-emitting element 140a disposed in the 2-1 subpixel SP2a and a 2-2 light-emitting element 140b disposed in the 2-2 subpixel SP2b. The third light-emitting element 150 can include a 3-1 light-emitting element 150a disposed in the 3-1 subpixel SP3a and a 3-2 light-emitting element 150b disposed in the 3-2 subpixel SP3b.

Referring to FIG. 6, a second electrode CE2 can be disposed in each of the plurality of subpixels. The second electrode CE2 can be disposed on the light-emitting element ED. The second electrode CE2 can be electrically connected to the pixel driving circuit PD through a plurality of contact electrodes CCE.

For example, the second electrode CE2 can be electrically connected to a cathode electrode (135 in FIG. 8) of the light-emitting element ED to transmit a cathode voltage from the pixel driving circuit PD to the light-emitting element ED. The same cathode voltage can be applied to the second electrode CE2 of each of the plurality of subpixels. For example, the same voltage can be applied to the second electrode CE2 of each of the plurality of subpixels and the cathode electrode 135 of the light-emitting element ED. Accordingly, the second electrode CE2 can be a common electrode, but the embodiments of the present disclosure are not limited thereto.

At least some of the plurality of subpixels can share the second electrode CE2. At least some of the second electrodes CE2 of each of the plurality of subpixels can be electrically connected to each other. As the same voltage is applied to the second electrodes CE2, the second electrodes CE2 of at least some of the subpixels can be shared and used. For example, the second electrodes CE2 of at least some pixels PX of the plurality of pixels PX disposed in the same row can be connected to each other. For example, one second electrode CE2 can be disposed in the plurality of pixels PX. One second electrode CE2 can be disposed for every n subpixels.

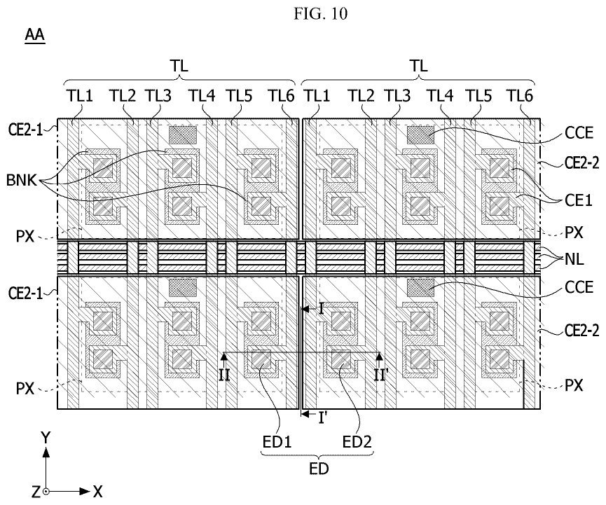

For example, referring to FIG. 10, some of the second electrodes CE2-1, CE2-2, of each of the plurality of subpixels can be disposed to be spaced apart or separated from each other. For example, the second electrodes CE2-1 and CE2-2 connected to pixels PX in an nth row and the second electrodes CE2-1 and CE2-2 connected to pixels PX in an n+1th row can be disposed to be spaced apart or separated from each other. Further, the second electrodes CE2-1 and CE2-2 connected to the pixels PX in the nth row can be disposed to be spaced apart or separated from each other. In addition, the second electrodes CE2-1 and CE2-2 connected to the pixels PX in the n+1th row can be disposed to be spaced apart or separated from each other.

Here, the plurality of second electrodes CE2-1 or CE2-2 disposed in the same column can be disposed spaced apart from each other with the plurality of communication lines NL extending in the row direction therebetween. Further, the plurality of second electrodes CE2-1 and CE2-2 disposed in the nth row that is the same row can be disposed spaced apart from each other with the signal lines TL extending in the column direction therebetween. In addition, the plurality of second electrodes CE2-1 and CE2-2 disposed in the n+1th row that is the same row can be spaced apart from each other with the signal lines TL extending in the column direction therebetween.

Accordingly, the number of subpixels can be greater than the number of second electrodes CE2. For another example, all the second electrodes CE2 of the plurality of subpixel s can be connected to each other and thus only one second electrode CE2 can be disposed on the substrate 110, but the embodiments of the present disclosure are not limited thereto.

The plurality of second electrodes CE2 can be composed of a transparent conductive material, but the embodiments of the present disclosure are not limited thereto. The plurality of second electrodes CE2 can be formed of a transparent conductive material so that light emitted from the light-emitting element ED can be directed toward an upper portion of the second electrodes CE2. For example, the second electrode CE2 can be composed of a transparent conductive material such as indium tin oxide (ITO), indium zinc oxide (IZO), indium gallium zinc oxide (IGZO), or the like, but the embodiments of the present disclosure are not limited thereto.

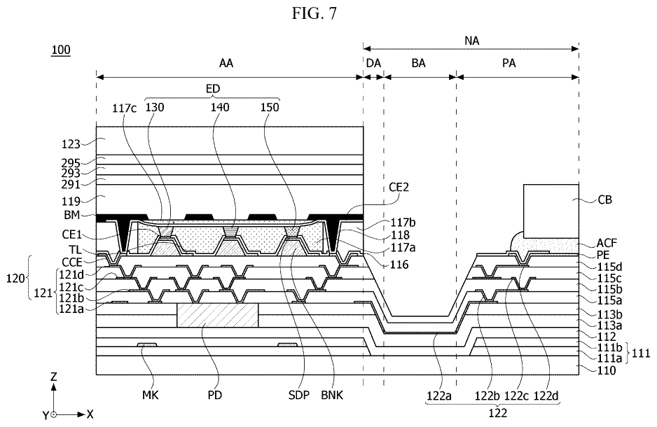

The plurality of contact electrodes CCE can be disposed on the substrate 110. For example, the plurality of contact electrodes CCE can be disposed spaced apart from the plurality of signal lines TL. Each of the plurality of second electrodes CE2 can overlap at least one contact electrode CCE. For example, one second electrode CE2 can overlap the plurality of contact electrodes CCE. The plurality of contact electrodes CCE can be electrically connected to the plurality of second electrodes CE2 through contact holes 118 formed in a second optical layer 117b (FIG. 7). The plurality of contact electrodes CCE can be disposed between the substrate 110 and the plurality of second electrodes CE2 and can transmit the cathode voltage from the pixel driving circuit PD to the second electrodes CE2.

For example, when micro LEDs are used as the light-emitting elements ED1 and ED2 (FIG. 10), the display device 1000 can be manufactured by forming a plurality of micro LEDs on a wafer and transferring the micro LEDs to the substrate 110 of the display device 1000. In the process of transferring the plurality of light-emitting elements ED1 and ED2 having a fine size from the wafer to the substrate 110, various defects can occur. For example, in some subpixels, a non-transfer defect in which the light-emitting element ED1 or ED2 are not transferred can occur, and in other subpixels, a defect in which the light-emitting element ED1 or ED2 is transferred to an incorrect position due to an alignment error can occur. Further, although the transfer process is normally performed, the transferred light-emitting element ED1 or ED2 itself can be defective. Accordingly, in consideration of defects during the transfer process of the plurality of light-emitting elements ED1 and ED2, the plurality of light-emitting elements ED1 and ED2 of the same type can be transferred to one subpixel. A lighting test can be performed on the plurality of light-emitting elements ED1 and ED2, and ultimately, only one light-emitting element ED that is determined to be normal can be used.

For example, referring to FIGS. 5 and 6, the 1-1 light-emitting element 130a and the 1-2 light-emitting element 130b can be transferred together to one pixel PX and inspected for defects. When both the 1-1 light-emitting element 130a and the 1-2 light-emitting element 130b are determined to be normal, only the 1-1 light-emitting element 130a can be used and the 1-2 light-emitting element 130b may not be used. For another example, when only the 1-2 light-emitting element 130b is determined to be normal among the 1-1 light-emitting element 130a and the 1-2 light-emitting element 130b, the 1-1 light-emitting element 130a may not be used and only the 1-2 light-emitting element 130b can be used. Accordingly, even when the plurality of light-emitting elements ED of the same type are transferred to one pixel PX, ultimately, only one light-emitting element ED can be used.

Accordingly, one of the pair of light-emitting elements ED can be a main (or primary) light-emitting element ED and the other can be a redundancy light-emitting element ED. The redundancy light-emitting element ED can be a spare light-emitting element ED transferred to prepare for a defective main light-emitting element ED. When the main light-emitting element ED is defective, the redundancy light-emitting element ED can be used as a replacement. Accordingly, the deterioration of display quality due to the defects of the main light-emitting element ED and the redundancy light-emitting element ED can be minimized by transferring the main light-emitting element ED and the redundancy light-emitting element ED together to one pixel PX.

For example, the 1-1 light-emitting element 130a, the 2-1 light-emitting element 140a, and the 3-1 light-emitting element 150a transferred to one pixel PX can be used as the main light-emitting elements ED, and the 1-2 light-emitting element 130b, the 2-2 light-emitting element 140b, and the 3-2 light-emitting element 150b can be used as the redundancy light-emitting elements ED.

FIG. 7 is a cross-sectional view of a display panel of the display device according to the embodiments of the present disclosure. FIG. 8 is an enlarged partial cross-sectional view of a sub-pixel of the display device according to the embodiments of the present disclosure. For example, FIG. 7 is a cross-sectional view of the display region AA, the dummy region DA, the bending region BA, and the pad region PA of the display panel.

Referring to FIG. 7, a buffer layer 111 can be disposed on the remaining regions of the substrate 110 excluding the bending region BA. The buffer layer 111 can include a first buffer layer 111a and a second buffer layer 111b.

The first buffer layer 111a and the second buffer layer 111b can be disposed in the display region AA, the dummy region DA, and the pad region PA. The first buffer layer 111a and the second buffer layer 111b can reduce the penetration of moisture or impurities through the substrate 110. The first buffer layer 111a and the second buffer layer 111b can be formed of an inorganic insulating material. For example, the first buffer layer 111a and the second buffer layer 111b can be composed of a single layer or multiple layers of silicon oxide (SiOₓ) or silicon nitride (SiNₓ), but the embodiments of the present disclosure are not limited thereto.

The non-display region NA can include the dummy region DA, the bending region BA, and the pad region PA. The first and second buffer layers 111a and 111b can be disposed in the dummy region DA and the pad region PA, and can be removed in the bending region BA. For example, the buffer layer 111 can be composed of a single layer or multiple layers of silicon oxide (SiOₓ) or silicon nitride (SiNₓ) which is an inorganic film material, but the embodiments of the present disclosure are not limited thereto. For example, portions of the first buffer layer 111a and the second buffer layer 111b in the bending region BA can be removed. An upper surface of the substrate 110 located in the bending region BA can be exposed from the first buffer layer 111a and the second buffer layer 111b. Cracks in the first buffer layer 111a and the second buffer layer 111b which can occur during bending can be minimized by removing the first buffer layer 111a and the second buffer layer 111b formed of an inorganic insulating material from the bending region BA.

A plurality of alignment keys MK can be disposed between the first buffer layer 111a and the second buffer layer 111b. The plurality of alignment keys MK can be configured to identify a position of the pixel driving circuit PD during the manufacturing process of the display device 1000. For example, the plurality of alignment keys MK can be configured to align the position of the pixel driving circuit PD transferred onto a circuit adhesive layer 112. For another example, the plurality of alignment keys MK can be omitted.

The circuit adhesive layer 112 can be disposed on the second buffer layer 111b. The circuit adhesive layer 112 can be disposed in the display region AA and the non-display region NA. For another example, at least a portion of the circuit adhesive layer 112 can be removed in the non-display region NA including the bending region BA. For example, the circuit adhesive layer 112 can be formed of any one of an adhesive polymer, an epoxy resin, a UV-curable resin, a polyimide-based material, an acrylate-based material, a urethane-based material, and polydimethylsiloxane (PDMS), but the embodiments of the present disclosure are not limited thereto.

The pixel driving circuit PD can be disposed on the circuit adhesive layer 112 in the display region AA. When the pixel driving circuit PD is implemented as a driver, the driver can be mounted on the circuit adhesive layer 112 by a transfer process, but the embodiments of the present disclosure are not limited thereto.

A first protective layer 113a and a second protective layer 113b can be disposed on the adhesive layer 112 on which the pixel driving circuit PD is disposed. The first protective layer 113a and the second protective layer 113b can be disposed to surround the sides of the pixel driving circuit PD, but the embodiments of the present disclosure are not limited thereto. For example, the second protective layer 113b can be disposed to cover at least a portion of an upper surface of the pixel driving circuit PD. For example, at least one of the first protective layer 113a and the second protective layer 113b disposed in the bending region BA can be omitted. For example, the first and second protective layers 113a and 113b can be entirely disposed in the display region AA and the non-display region NA. For example, a portion of the second protective layer 113b in the bending region BA can be removed. However, the embodiments of the present disclosure are not limited thereto.

The first protective layer 113a and the second protective layer 113b can be composed of an organic insulating material, but the embodiments of the present disclosure are not limited thereto. For example, the first protective layer 113a and the second protective layer 113b can be composed of a photoresist, a polyimide (PI)-based material, a photo acrylic-based material, or the like, but the embodiments of the present disclosure are not limited thereto. For example, the first protective layer 113a and the second protective layer 113b can be overcoating layers or insulating layers, but the embodiments of the present disclosure are not limited thereto.

A plurality of first connection lines 121 can be disposed on the second protective layer 113b in the display region AA. The plurality of first connection lines 121 can be lines for electrically connecting the pixel driving circuit PD to other components. For example, the pixel driving circuit PD can be electrically connected to the plurality of signal lines TL, the plurality of contact electrodes CCE, and the like through the plurality of first connection lines 121. For example, the plurality of first connection lines 121 can include a 1-1 connection line 121a, a 1-2 connection line 121b, a 1-3 connection line 121c, and a 1-4 connection line 121d, but the embodiments of the present disclosure are not limited thereto.

For example, a plurality of 1-1 connection lines 121a can be disposed on the second protective layer 113b. The plurality of 1-1 connection lines 121a can be electrically connected to the pixel driving circuit PD. The plurality of 1-1 connection lines 121a can transmit a voltage output from the pixel driving circuit PD to the first electrode CE1 or the second electrode CE2.

For example, the first and second protective layers 113a and 113b can be composed of an organic insulating material. For example, the first and second protective layers 113a and 113b can be composed of a photoresist, a polyimide (PI)-based material, a photo acrylic-based material, or the like, but the embodiments of the present disclosure are not limited thereto. For example, the first protective layer 113a and the second protective layer 113b can be composed of the same material, but the embodiments of the present disclosure are not limited thereto.

An inorganic insulating layer can be disposed on the second protective layer 113b on which the plurality of 1-1 connection lines 121a are disposed. For example, the inorganic insulating layer can be composed of a single layer or multiple layers of silicon oxide (SiOₓ) or silicon nitride (SiNₓ) which is an inorganic film material, but the embodiments of the present disclosure are not limited thereto.

A first organic insulating layer 115a can be disposed on the inorganic insulating layer (not shown). The first organic insulating layer 115a can be composed of an organic insulating material, but the embodiments of the present disclosure are not limited thereto. For example, the first organic insulating layer 115a can be composed of a photoresist, a polyimide (PI)-based material, a photo acrylic-based material, or the like, but the embodiments of the present disclosure are not limited thereto.

Further, a plurality of 1-2 connection lines 121b can be disposed on the first organic insulating layer 115a. The plurality of 1-2 connection lines 121b can be connected to or directly connected to the pixel driving circuit PD. For example, some of the 1-2 connection lines 121b can be directly connected to the pixel driving circuit PD through contact holes of the inorganic insulating layer and the first organic insulating layer 115a. Other 1-2 connection lines 121b can be electrically connected to the 1-1 connection lines 121a through contact holes of the inorganic insulating layer and the first organic insulating layer 115a. However, the embodiments of the present disclosure are not limited thereto. The voltage output from the pixel driving circuit PD can be transmitted to the first electrode CE1 or the second electrode CE2 through the plurality of 1-2 connection lines 121b and other connection lines.

A second organic insulating layer 115b can be disposed on the plurality of 1-2 connection lines 121b. The second organic insulating layer 115b can be entirely disposed in the display region AA and the non-display region NA, but the embodiments of the present disclosure are not limited thereto. The second organic insulating layer 115b can be composed of an organic insulating material, but the embodiments of the present disclosure are not limited thereto. For example, the second organic insulating layer 115b can be composed of a photoresist, a polyimide (PI)-based material, a photo acrylic-based material, or the like, but the embodiments of the present disclosure are not limited thereto.

A plurality of 1-3 connection lines 121c can be disposed on the second organic insulating layer 115b. The plurality of 1-3 connection lines 121c can be electrically connected to the plurality of 1-2 connection lines 121b. For example, the 1-3 connection lines 121c can be electrically connected to the 1-2 connection lines 121b through contact holes of the second organic insulating layer 115b.

A third organic insulating layer 115c can be disposed on the plurality of 1-3 connection lines 121c. The third organic insulating layer 115c can be disposed in the remaining region excluding the bending region BA, but the embodiments of the present disclosure are not limited thereto. The third organic insulating layer 115c can be disposed in the display region AA, the dummy region DA, and the pad region PA, but the embodiments of the present disclosure are not limited thereto. For example, a portion of the third organic insulating layer 115c disposed in the bending region BA can be removed. The third organic insulating layer 115c can be composed of an organic insulating material, but the embodiments of the present disclosure are not limited thereto. For example, the third organic insulating layer 115c can be composed of a photoresist, a polyimide (PI)-based material, a photo acrylic-based material, or the like, but the embodiments of the present disclosure are not limited thereto.

A plurality of 1-4 connection lines 121d can be disposed on the third organic insulating layer 115c. The plurality of 1-4 connection lines 121d can be electrically connected to the plurality of 1-3 connection lines 121c. For example, the 1-4 connection lines 121d can be electrically connected to the 1-3 connection lines 121c through contact holes of the third organic insulating layer 115c.

A fourth organic insulating layer 115d can be disposed on the plurality of 1-4 connection lines 121d. The fourth organic insulating layer 115d can be disposed in the remaining region excluding the bending region BA, but the embodiments of the present disclosure are not limited thereto. The fourth organic insulating layer 115d can be disposed in the display region AA, the dummy region DA, and the pad region PA, but the embodiments of the present disclosure are not limited thereto.

Further, the circuit layer 120 can include the pixel driving circuit PD, the plurality of connection lines 121 and 122, the signal lines TL, and the like. The present disclosure is not limited thereto.

According to the present disclosure, a plurality of second connection lines 122 can be disposed on the second protective layer 113b in the non-display region NA. The plurality of second connection lines 122 can be lines for transmitting signals transmitted from the flexible circuit board (or flexible film) CB and the printed circuit board 160 (see FIG. 1) to the pad portion PAD to the pixel driving circuit PD of the display region AA. For example, the plurality of second connection lines 122 can be electrically connected to the plurality of pad electrodes PE to receive signals from the flexible circuit board (or flexible film) CB and the printed circuit board 160.

For example, the plurality of second connection lines 122 can extend from the pad portion PAD toward the display region AA and transmit the signals to lines in the display region AA. In this case, the plurality of second connection lines 122 can function as link lines LL. The plurality of second connection lines 122 can include a 2-1 connection line 122a, a 2-2 connection line 122b, a 2-3 connection line 122c, and a 2-4 connection line 122d.

A plurality of 2-1 connection lines 122a can be disposed on the second protective layer 113b. The plurality of 2-1 connection lines 122a can extend from the pad region PA to the bending region BA and the dummy region DA. The plurality of 2-1 connection lines 122a can transmit the signals transmitted from the flexible circuit board (or flexible film) CB and the printed circuit board to the pad portion PAD to the pixel driving circuit PD of the display region AA.

A plurality of 2-2 connection lines 122b can be disposed on the inorganic insulating layer and the first organic insulating layer 115a. The plurality of 2-2 connection lines 122b can be disposed in the pad region PA. The 2-2 connection lines 122b can be electrically connected to the 2-1 connection lines 122a through contact holes of the inorganic insulating layer and the first organic insulating layer 115a. Accordingly, the signals from the flexible circuit board (or flexible film) CB and the printed circuit board can be transmitted to the 2-1 connection lines 122a through the 2-2 connection lines 122b.

The 2-3 connection line 122c can be disposed on the second organic insulating layer 115b. The 2-3 connection line 122c can be disposed in the pad region PA. The 2-3 connection line 122c can be electrically connected to the 2-2 connection lines 122b through a contact hole of the second organic insulating layer 115b. Accordingly, the signals from the flexible circuit board (or flexible film) CB and the printed circuit board can be transmitted to the 2-1 connection lines 122a through the 2-3 connection line 122c and the 2-2 connection lines 122b.

The third organic insulating layer 115c can be disposed on the second organic insulating layer 115b and the 2-3 connection line 122c. The 2-4 connection line 122d can be disposed on the third organic insulating layer 115c. The 2-4 connection line 122d can be disposed in the pad region PA. The 2-4 connection line 122d can be electrically connected to the 2-3 connection line 122c through a contact hole of the third organic insulating layer 115c. Accordingly, the signals from the flexible circuit board (or flexible film) CB and the printed circuit board can be transmitted to the 2-1 connection lines 122a through the 2-4 connection line 122d, the 2-3 connection line 122c, and the 2-2 connection lines 122b.

The plurality of first connection lines 121 and the plurality of second connection lines 122 can be formed of a conductive material having excellent flexibility or any one of various conductive materials used in the display region AA. For example, the second connection line 122 partially disposed in the bending region BA can be composed of a conductive material having excellent flexibility such as gold (Au), silver (Ag), aluminum (Al), or the like, but the embodiments of the present disclosure are not limited thereto. For another example, the plurality of first connection lines 121 and the plurality of second connection lines 122 can be composed of molybdenum (Mo), chromium (Cr), titanium (Ti), nickel (Ni), neodymium (Nd), copper (Cu), and an alloy of silver (Ag) and magnesium (Mg), or an alloy thereof, but the embodiments of the present disclosure are not limited thereto.

The fourth organic insulating layer 115d can be disposed on the plurality of first connection lines 121 and the plurality of second connection lines 122. The fourth organic insulating layer 115d can be disposed in the remaining region excluding the bending region BA, but the embodiments of the present disclosure are not limited thereto. The fourth organic insulating layer 115d can be disposed in the display region AA, the dummy region DA, and the pad region PA. A portion of the fourth organic insulating layer 115d disposed in the bending region BA can be removed. The fourth organic insulating layer 115d can be composed of an organic insulating material, but the embodiments of the present disclosure are not limited thereto. For example, the fourth organic insulating layer 115d can be composed of a photoresist, a polyimide (PI)-based material, a photo acrylic-based material, or the like, but the embodiments of the present disclosure are not limited thereto.

The plurality of banks BNK can be disposed on the fourth organic insulating layer 115d in the display region AA. The plurality of banks BNK can be disposed to overlap the plurality of subpixels, respectively. One or more light-emitting elements ED of the same type can be disposed on each of the plurality of banks BNK.

The plurality of signal lines TL can be disposed on the fourth organic insulating layer 115d in the display region AA. The plurality of signal lines TL can be disposed in regions between the plurality of banks BNK. For example, the plurality of signal lines TL can be disposed adjacent to any one of the plurality of banks BNK.

The plurality of contact electrodes CCE can be disposed on the fourth organic insulating layer 115d in the display region AA. The plurality of contact electrodes CCE can supply the cathode voltage from the pixel driving circuit PD to the second electrode CE2.

The first electrode CE1 can be disposed on the bank BNK. For example, the first electrode CE1 can be disposed to extend from adjacent signal line TL toward an upper portion of the bank BNK. The first electrode CE1 can be disposed on an upper surface of the bank BNK and a side surface of the bank BNK. For example, the first electrode CE1 can be disposed to extend from the signal line TL on the upper surface of the fourth organic insulating layer 115d to the side surface of the bank BNK and the upper surface of the bank BNK.

Referring to FIGS. 7 and 8, the first electrode CE1 can be composed of a plurality of conductive layers. For example, the first electrode CE1 can include a first conductive layer CE1a, a second conductive layer CE1b, a third conductive layer CE1c, and a fourth conductive layer CE1d, but the embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, each of the first conductive layer CE1a, the second conductive layer CE1b, the third conductive layer CE1c, and the fourth conductive layer CE1d can be composed of titanium (Ti), molybdenum (Mo), aluminum (Al), or indium tin oxide (ITO), but the embodiments of the present disclosure are not limited thereto.

According to the present disclosure, some conductive layers having excellent reflection efficiency among the plurality of conductive layers constituting the first electrode CE1 can be configured as alignment keys for aligning the light-emitting elements ED and/or reflective plates. For example, the second conductive layer CE1b among the plurality of conductive layers of the first electrode CE1 can include a reflective material. For example, the second conductive layer CE1b can include aluminum (Al), but the embodiments of the present disclosure are not limited thereto. Accordingly, the second conductive layer CE1b can be configured as a reflective plate. Further, identification in the manufacturing process can be easy due to the high reflective efficiency of the second conductive layer CE1b, and thus a position or transfer position of the light-emitting element ED can be aligned based on the second conductive layer CE1b.

For example, in order to configure the second conductive layer CE1b as a reflective plate, the third conductive layer CE1c and the fourth conductive layer CE1d which cover the second conductive layer CE1b can be partially removed or etched. For example, portions of the third conductive layer CE1c and fourth conductive layer CE1d disposed on the bank BNK can be removed or etched to expose an upper surface of the second conductive layer CE1b. For example, in the third conductive layer CE1c and the fourth conductive layer CE1d, center portions where a solder pattern SDP is disposed and edge portions can be left, and the remaining portion can be removed. For example, the edge portion of each of the third conductive layer CE1c made of titanium (Ti) and the fourth conductive layer CE1d made of indium tin oxide (ITO) may not be etched. Accordingly, it is possible to prevent other conductive layers of the first electrode CE1 from being corroded by a tetramethylammonium hydroxide (TMAH) solution used in a mask process of the first electrode CE1.

According to the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer such as indium tin oxide (ITO) or indium zinc oxide (IZO) having excellent adhesion to the solder pattern SDP and having corrosion resistance and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process, but the embodiments of the present disclosure are not limited thereto.

According to the present disclosure, the signal line TL, the contact electrode CCE, and the pad electrode PE disposed on the same layer as the first electrode CE1 can be composed of multiple layers of a conductive material, but the embodiments of the present disclosure are not limited thereto. For example, the signal line TL, the contact electrode CCE, and the pad electrode PE can be formed of multiple layers of indium tin oxide (ITO)/titanium (Ti)/aluminum (Al)/titanium (Ti), but the embodiments of the present disclosure are not limited thereto.

According to the present disclosure, the solder pattern SDP can be disposed on the first electrode CE1 in each of the plurality of subpixels. The solder pattern SDP can bond the light-emitting element ED to the first electrode CE1. The first electrode CE1 and the light-emitting element ED can be electrically connected by eutectic bonding using the solder pattern SDP, but the embodiments of the present disclosure are not limited thereto. For example, when the solder pattern SDP is composed of indium (In) and the anode electrode 134 of the light-emitting element ED is composed of gold (Au), the solder pattern SDP and the anode electrode 134 can be bonded by applying heat and pressure in the transfer process of the light-emitting element ED. The light-emitting element ED can be bonded to the solder pattern SDP and the first electrode CE1 by eutectic bonding without a separate adhesive. For example, the solder pattern SDP can be composed of indium (In), tin (Sn), or an alloy thereof, but the embodiments of the present disclosure are not limited thereto. For example, the solder pattern SDP can be a bonding pad or a joining pad, but the embodiments of the present disclosure are not limited thereto.

Further, referring to FIG. 7, an insulating layer 116 can be disposed on the fourth organic insulating layer 115d, the first electrode CE1 and the bank BNK. For example, the insulating layer 116 can be entirely disposed in the display region AA and the non-display region NA. The insulating layer 116 can be composed of a single layer or multiple layers of silicon oxide (SiOₓ) or silicon nitride (SiNₓ) which is an inorganic film material, but the embodiments of the present disclosure are not limited thereto.

According to the present disclosure, the insulating layer 116 which functions as a passivation layer can be disposed on the plurality of signal lines TL, the plurality of first electrodes CE1, the plurality of contact electrodes CCE, and the fourth organic insulating layer 115d. For example, the insulating layer 116 can be disposed in the display region AA, the dummy region DA, and the pad region PA. A portion of the insulating layer 116 disposed in the bending region BA can be removed. A portion of the insulating layer 116 covering the plurality of pad electrodes PE in the pad region PA can be removed. Since the insulating layer 116 is disposed to cover the remaining region excluding regions where the bending region BA, the plurality of pad electrodes PE, and the solder pattern SDP are disposed, the penetration of moisture or impurities into the light-emitting element ED can be reduced. For example, the insulating layer 116 can be composed of a single layer or multiple layers of silicon oxide (SiOₓ) or silicon nitride (SiNₓ) which is an inorganic film material, but the embodiments of the present disclosure are not limited thereto. For example, the insulating layer 116 can be a protective layer or an insulating layer, but the embodiments of the present disclosure are not limited thereto. Further, the insulating layer 116 can include a hole which exposes the solder pattern SDP.

The light-emitting element ED can be disposed on the solder pattern SDP in each of the plurality of subpixels. The first light-emitting element 130 can be disposed in the first subpixel SP1. The second light-emitting element 140 can be disposed in the second subpixel SP2. The third light-emitting element 150 can be disposed in the third subpixel SP3.

The light-emitting element ED can be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like, but the embodiments of the present disclosure are not limited thereto.

Referring to FIGS. 8, the first light-emitting element 130 can include the anode electrode 134, a first semiconductor layer 131, an active layer 132, a second semiconductor layer 133, the cathode electrode 135, and an encapsulation film 136, but the embodiments of the present disclosure are not limited thereto. For example, the first light-emitting element 130 may not include the encapsulation film 136. The first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be implemented with a group III-V compound semiconductor, a group II-VI compound semiconductor, or the like, and can be doped with impurities (or dopant). For example, one of the first semiconductor layer 131 and the second semiconductor layer 133 can be a semiconductor layer doped with n-type impurities and the other can be a semiconductor layer doped with p-type impurities, but the embodiments of the present disclosure are not limited thereto. For example, one or more of the first semiconductor layer 131 and the second semiconductor layer 133 can be layers in which a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), gallium arsenide (GaAs), or the like is doped with n-type impurities or p-type impurities, but the embodiments of the present disclosure are not limited thereto. For example, the n-type impurities can be silicon (Si), germanium (Ge), selenium (Se), carbon (C), tellurium (Te), tin (Sn), or the like, but the embodiments of the present disclosure are not limited thereto. For example, the p-type impurities can be magnesium (Mg), zinc (Zn), calcium (Ca), strontium (Sr), barium (Ba), beryllium (Be), or the like, but the embodiments of the present disclosure are not limited thereto.

For example, the first semiconductor layer 131 and the second semiconductor layer 133 can be a nitride semiconductor containing n-type impurities and a nitride semiconductor containing p-type impurities, respectively, but the embodiments of the present disclosure are not limited thereto. For example, the first semiconductor layer 131 can be a nitride semiconductor containing p-type impurities, and the second semiconductor layer 133 can be a nitride semiconductor containing n-type impurities, but the embodiments of the present disclosure are not limited thereto.

The active layer 132 can be disposed between the first semiconductor layer 131 and the second semiconductor layer 133. The active layer 132 can receive holes and electrons from the first semiconductor layer 131 and the second semiconductor layer 133 and emit light. For example, the active layer 132 can have any one of a single well structure, a multi-well structure, a single quantum well structure, a multi quantum well (MQW) structure, a quantum dot structure, and a quantum line structure, but the embodiments of the present disclosure are not limited thereto. For example, the active layer 132 can be composed of indium gallium nitride (InGaN) or gallium nitride (GaN), but the embodiments of the present disclosure are not limited thereto.

For another example, the active layer 132 can include a multi quantum well (MQW) structure having a well layer and a barrier layer having a higher band gap than the well layer. For example, the active layer 132 can include an InGaN well layer and an AlGaN barrier layer, but the embodiments of the present disclosure are not limited thereto.

The anode electrode 134 can be disposed between the first semiconductor layer 131 and the solder pattern SDP. For example, the anode electrode 134 can electrically connect the first semiconductor layer 131 and the first electrode CE1. The anode voltage output from the pixel driving circuit PD can be applied to the first semiconductor layer 131 through the signal line TL, the first electrode CE1, and the anode electrode 134. For example, the anode electrode 134 can be composed of a conductive material which can be eutectically bonded to the solder pattern SDP, but the embodiments of the present disclosure are not limited thereto. For example, the anode electrode 134 can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the embodiments of the present disclosure are not limited thereto.

The cathode electrode 135 can be disposed on the second semiconductor layer 133. For example, the cathode electrode 135 can electrically connect the second semiconductor layer 133 and the second electrode CE2. The cathode voltage output from the pixel driving circuit PD can be applied to the second semiconductor layer 133 through the contact electrode CCE, the second electrode CE2, and the cathode electrode 135. The cathode electrode 135 can be composed of a transparent conductive material so that light emitted from the light-emitting element ED can be directed toward an upper portion of the light-emitting element ED, but the embodiments of the present disclosure are not limited thereto. For example, the cathode electrode 135 can be composed of a material such as indium tin oxide (ITO), indium zinc oxide (IZO), or indium gallium zinc oxide (IGZO), but the embodiments of the present disclosure are not limited thereto.

The encapsulation film 136 can be disposed on at least portions of the first semiconductor layer 131, the active layer 132, the second semiconductor layer 133, the anode electrode 134, and the cathode electrode 135. For example, the encapsulation film 136 can surround at least portions of the first semiconductor layer 131, the active layer 132, the second semiconductor layer 133, the anode electrode 134, and the cathode electrode 135. For example, the encapsulation film 136 can protect the first semiconductor layer 131, the active layer 132, and the second semiconductor layer 133. For example, the encapsulation film 136 can be disposed on a side surface of the first semiconductor layer 131, a side surface of the active layer 132, and a side surface of the second semiconductor layer 133.

For example, the encapsulation film 136 can be disposed on at least portions of the anode electrode 134 and the cathode electrode 135, for example, an edge portion (or one side) of the anode electrode 134 and an edge portion (or one side) of the cathode electrode 135. Since at least a portion of the anode electrode 134 can be exposed from the encapsulation film 136, the anode electrode 134 and the solder pattern SDP can be connected. For example, since at least a portion of the cathode electrode 135 can be exposed from the encapsulation film 136, the cathode electrode 135 and the second electrode CE2 can be connected. For example, the encapsulation film 136 can be formed of an insulating material such as silicon nitride (SiNₓ) or silicon oxide (SiOₓ), but the embodiments of the present disclosure are not limited thereto.

For another example, the encapsulation film 136 can have a structure in which a reflective material is dispersed in a resin layer, but the embodiments of the present disclosure are not limited thereto. For example, the encapsulation film 136 can be manufactured as a reflector having various structures, but the embodiments of the present disclosure are not limited thereto. Since light emitted from the active layer 132 can be reflected upward by the encapsulation film 136, light extraction efficiency can be enhanced. For example, the encapsulation film 136 can be a reflective layer, but the embodiments of the present disclosure are not limited thereto.

According to the present disclosure, although the light-emitting element ED is described as having a vertical structure, the embodiments of the present disclosure are not limited thereto. For example, the light-emitting element ED can have a lateral structure or a flip chip structure.

Although the first light-emitting element 130 has been described referring to FIG. 8, the second light-emitting element 140 and the third light-emitting element 150 can have substantially the same structure as the first light-emitting element 130. For example, the structures of the second light-emitting element 140 and the third light-emitting element 150 can be substantially the same as the first semiconductor layer 131, the active layer 132, the second semiconductor layer 133, the anode electrode 134, the cathode electrode 135, and the encapsulation film 136 of the first light-emitting element 130.

According to the present disclosure, a first optical layer 117a surrounding the plurality of light-emitting elements ED in the display region AA can be disposed on the insulating layer 116. For example, the first optical layer 117a can be disposed to cover the plurality of light-emitting elements ED and the plurality of banks BNK in regions of the plurality of subpixels. For example, the first optical layer 117a can cover the bank BNK, a portion of the insulating layer 116, and a space between the plurality of light-emitting elements ED. The first optical layer 117a can be disposed between the plurality of light-emitting elements ED included in one pixel PX and between the plurality of banks BNK or can cover spaces between the plurality of light-emitting elements ED and between the plurality of banks BNK. For example, the first optical layers 117a can extend in the first direction (X) and can be disposed spaced apart from each other in the second direction (Y). For example, the first optical layer 117a can be disposed between the insulating layer 116 and the second electrode CE2 to surround side portions of the light-emitting element ED and the bank BNK, but the embodiments of the present disclosure are not limited thereto. For example, the first optical layer 117a can be a diffusion layer, a sidewall diffusion layer, or the like, but the embodiments of the present disclosure are not limited thereto.

The first optical layer 117a can include an organic insulating material in which fine particles are dispersed, but the embodiments of the present disclosure are not limited thereto. For example, the first optical layer 117a can be composed of siloxane in which fine metal particles such as titanium dioxide (TiO₂) particles are dispersed, but the embodiments of the present disclosure are not limited thereto. Light from the plurality of light-emitting elements ED can be scattered by the fine particles dispersed in the first optical layer 117a and emitted to the outside of the display device 1000. Accordingly, the first optical layer 117a can enhance the extraction efficiency of the light emitted from the plurality of light-emitting elements ED.

For example, the first optical layer 117a can be disposed in each of the plurality of pixels PX, or can be disposed together in some of the pixels PX disposed in the same row, but the embodiments of the present disclosure are not limited thereto. For example, the first optical layer 117a can be disposed in each of the plurality of pixels PX, or the plurality of pixels PX can share one first optical layer 117a. For another example, each of the plurality of subpixels can separately include the first optical layer 117a, but the embodiments of the present disclosure are not limited thereto.

According to the present disclosure, a second optical layer 117b can be disposed on the insulating layer 116 in the display region AA. For example, the second optical layer 117b can be disposed to surround the first optical layer 117a. For example, the second optical layer 117b can be in contact with a side surface of the first optical layer 117a. For example, the second optical layer 117b can be disposed in the region between the plurality of pixels PX. However, the embodiments of the present disclosure are not limited thereto. For example, the second optical layer 117b can be a diffusion layer, a diffusion layer window, a window diffusion layer, or the like, but the embodiments of the present disclosure are not limited thereto.

The second optical layer 117b can be composed of an organic insulating material, but the embodiments of the present disclosure are not limited thereto. The second optical layer 117b can be composed of the same material as the first optical layer 117a, but the embodiments of the present disclosure are not limited thereto. For example, the first optical layer 117a can include fine particles, and the second optical layer 117b may not include fine particles. For example, the second optical layer 117b can be formed of siloxane, but the embodiments of the present disclosure are not limited thereto.

For example, a thickness of the first optical layer 117a can be less than a thickness of the second optical layer 117b, but the embodiments of the present disclosure are not limited thereto. Accordingly, when viewed in a cross-section view, a region where the first optical layer 117a is disposed can include a groove portion recessed downward from an upper surface of the second optical layer 117b.

According to the present disclosure, the second electrode CE2 can be disposed on the first optical layer 117a and the second optical layer 117b. For example, the second electrode CE2 can be electrically connected to the plurality of contact electrodes CCE through contact holes of the second optical layer 117b. For example, the second electrode CE2 can be disposed on the plurality of light-emitting elements ED. For example, the second electrode CE2 can include a transparent conductive oxide such as indium tin oxide (ITO), indium zinc oxide (IZO), or the like, but the embodiments of the present disclosure are not limited thereto. For example, the second electrode CE2 can be disposed to be in contact with the cathode electrode 135. For example, the second electrode CE2 can overlap the first optical layer 117a. For example, the second electrode CE2 can cover an outer flat surface of the first optical layer 117a.

The second electrode CE2 can continuously extend in the first direction (X) of the substrate 110.

Accordingly, the second electrode CE2 can be connected to the plurality of pixels PX disposed in the first direction (X) of the substrate 110, in common. For example, the second electrode CE2 can be connected to the plurality of pixels PX in common.

According to the present disclosure, the second electrode CE2 can continuously extend on the first optical layer 117a, the second optical layer 117b, and the light-emitting element ED. The region where the first optical layer 117a is disposed can include a concave portion recessed downward from the upper surface of the second optical layer 117b. Accordingly, a first portion of the second electrode CE2 disposed on the first optical layer 117a is disposed along the concave portion, and thus can be disposed at a lower position than a second portion of the second electrode CE2 disposed on the second optical layer 117b.

Further, a third optical layer 117c can be disposed on the second electrode CE2. The third optical layer 117c can be disposed to overlap the plurality of light-emitting elements ED and the first optical layer 117a. Since the third optical layer 117c is disposed on the second electrode CE2 and the plurality of light-emitting elements ED, the stain (mura) which can occur over some of the plurality of light-emitting elements ED can be improved. For example, when the plurality of light-emitting elements ED are transferred onto the substrate 110 of the display device 1000, a region where intervals between the plurality of light-emitting elements ED are not uniform can occur due to a process deviation or the like. When the intervals between the plurality of light-emitting elements ED are not uniform, a light-emitting region of each of the plurality of light-emitting elements ED can be disposed non-uniformly, and the stain (mura) can be visible to the user. Accordingly, since the third optical layer 117c is configured to uniformly diffuse light over the plurality of light-emitting elements ED, it is possible to reduce the light emitted from some of the light-emitting elements ED from being visible to the user as stain (mura).

Accordingly, since the light emitted from the plurality of light-emitting elements ED is uniformly diffused by the third optical layer 117c and extracted to the outside of the display device 1000, the brightness uniformity of the display device 1000 can be enhanced.

The third optical layer 117c can be composed of an organic insulating material in which fine particles are dispersed, but the embodiments of the present disclosure are not limited thereto. For example, the third optical layer 117c can be composed of siloxane in which fine metal particles such as titanium dioxide (TiO₂) particles are dispersed, but the embodiments of the present disclosure are not limited thereto. For example, the third optical layer 117c can be composed of the same material as the first optical layer 117a, but the embodiments of the present disclosure are not limited thereto. For example, the third optical layer 117c can be a diffusion layer or an upper surface diffusion layer, but the embodiments of the present disclosure are not limited thereto.

According to the present disclosure, light from the plurality of light-emitting elements ED can be scattered by the fine particles dispersed in the third optical layer 117c and emitted to the outside of the display device 1000. The third optical layer 117c can uniformly mix light emitted from the plurality of light-emitting elements ED to further enhance the brightness uniformity of the display device 1000. Further, the light extraction efficiency of the display device 1000 can be enhanced by the light scattered from the plurality of fine particles, and accordingly, the display device 1000 can be driven at low power.

A black matrix BM can be disposed on the second electrode CE2, the first optical layer 117a, the second optical layer 117b, and the third optical layer 117c in the display region AA. For example, the black matrix BM can fill a contact hole of the second optical layer 117b. The black matrix BM is configured to cover the display region AA, and thus can reduce the color mixing of light of the plurality of subpixels and external light reflection. For example, the black matrix BM is also disposed in the contact hole by which the second electrode CE2 and the contact electrode CCE are connected, and thus can prevent light leakage between the plurality of neighboring subpixels.

For example, the black matrix BM can be composed of an opaque material, but the embodiments of the present disclosure are not limited thereto. For example, the black matrix BM can be an organic insulating material to which a black pigment or black dye is added, but the embodiments of the present disclosure are not limited thereto.

A cover layer 119 can be disposed on the black matrix BM in the display region AA. The cover layer 119 can protect the configuration under the second electrode CE2. For example, the cover layer 119 can be composed an organic insulating material, but the embodiments of the present disclosure are not limited thereto. For example, the cover layer 119 can be composed of a photoresist, a polyimide (PI)-based material, a photo acrylic-based material, or the like, but the embodiments of the present disclosure are not limited thereto. For example, the cover layer 119 can be an overcoating layer or an insulating layer, but the embodiments of the present disclosure are not limited thereto.

The polarization layer 293 can be disposed on the cover layer 119 via a first adhesive layer 291 as shown in FIG. 1. The cover member 123 can be disposed on the polarization layer 293 via a cover adhesive layer 295. For example, the first adhesive layer 291 and the cover adhesive layer 295 can include an optically clear adhesive (OCA), an optically clear resin (OCR), a pressure sensitive adhesive (PSA), or the like, but the embodiments of the present disclosure are not limited thereto.

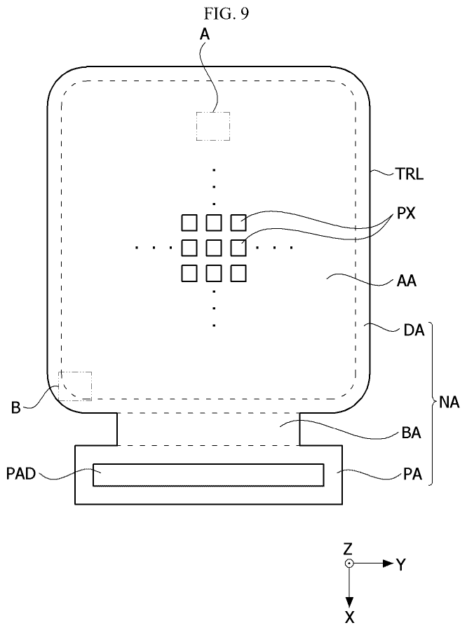

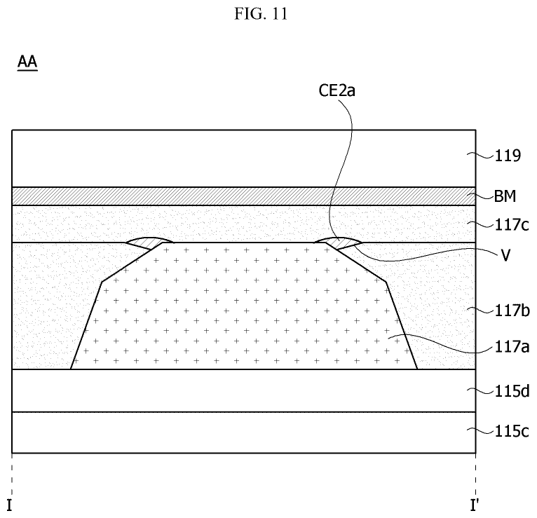

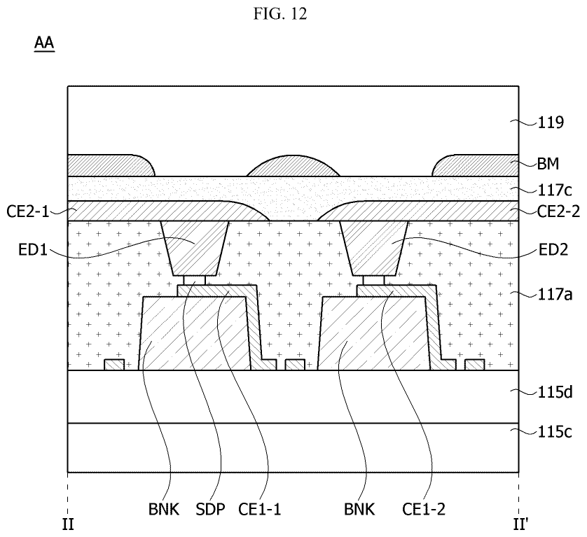

FIG. 9 is a plan view of the display device according to the embodiments of the present disclosure. FIG. 10 is an enlarged partial plan view of the display device according to the embodiments of the present disclosure. FIG. 11 is a cross-sectional view taken along line I-I′ in FIG. 10. FIG. 12 is a cross-sectional view taken along line II-II′ in FIG. 10.

Referring to FIGS. 9 and 10, the second electrode CE2 can be disposed on the plurality of light-emitting elements ED. The second electrode CE2 can be electrically connected to the pixel driving circuit (PD in FIG. 7) through plurality of contact electrodes CCE. Here, the plurality of light-emitting elements ED can include a plurality of light-emitting elements ED1 and a plurality of light-emitting elements ED2 disposed spaced apart from each other. The second electrode CE2 can include the plurality of second electrodes CE2-1 and CE2-2 spaced apart and separated from each other.

For example, each of the plurality of second electrodes CE2-1 and CE2-2 can be electrically connected to the cathode electrode (135 in FIG. 8) of the light-emitting element ED to transmit the cathode voltage from the pixel driving circuit PD to the plurality of light-emitting elements ED1 and ED2. The same cathode voltage can be applied to the second electrodes CE2-1 and CE2-2 of each of the plurality of subpixels.

At least some of the plurality of subpixels can share the second electrodes CE2-1 and CE2-2. At least some of the second electrodes CE2-1 and CE2-2 of each of the plurality of subpixels can be electrically connected to each other. As the same voltage is applied to the second electrodes CE2, the second electrodes CE2 of at least some of the subpixels can be shared and used. For example, the second electrodes CE2 of at least some pixels PX of the plurality of pixels PX disposed in the same row can be connected to each other. For example, one second electrode CE2 can be disposed in the plurality of pixels PX. One second electrode CE2 can be disposed for every n subpixel.

Specifically, referring to FIGS. 9 and 10, the plurality of second electrodes CE2-1 and CE2-2 disposed in the display region AA can be disposed to be spaced apart or separated from each other. For example, the second electrodes CE2-1 and CE2-2 connected to the pixels PX in the nth row and the second electrodes CE2-1 and CE2-2 connected to the pixels PX in the n+1th row can be disposed to be spaced apart or separated from each other. Further, the second electrodes CE2-1 and CE2-2 connected to the pixels PX in the nth row can be disposed to be spaced apart or separated from each other. In addition, the second electrodes CE2-1 and CE2-2 connected to the pixels PX in the n+1th row can be disposed to be spaced apart or separated from each other.

Here, the plurality of second electrodes CE2-1 and CE2-2 disposed in the display region AA can be disposed spaced apart from each other with the plurality of communication lines NL extending in the row direction therebetween. The plurality of second electrodes CE2-1 and CE2-2 disposed in the nth row that is the same row can be disposed spaced apart from each other with the signal lines TL extending in the column direction therebetween. Further, the plurality of second electrodes CE2-1 and CE2-2 disposed in the n+1th row that is the same row can be disposed spaced apart from each other with the signal lines TL extending in the column direction therebetween.

Accordingly, the number of subpixels can be greater than the number of second electrodes CE2. For another example, all the second electrodes CE2 of the plurality of subpixels can be connected to each other and thus only one second electrode CE2 can be disposed on the substrate 110, and the embodiments of the present disclosure are not limited thereto.

Referring to FIG. 11, in the display region AA, the first optical layer 117a can be disposed between the second electrodes CE2-1 and CE2-2 disposed spaced apart from each other in the same row, and the second optical layer 117b can be disposed on the side surface of the first optical layer 117a.

Here, a valley-shaped concave portion V can be formed at an upper end of a boundary region of the first optical layer 117a and the second optical layer 117b. Accordingly, in a process of etching a metal layer for forming the second electrodes CE2-1 and CE2-2 to form the second electrodes CE2-1 and CE2-2 on the first and second optical layers 117a and 117b, a phenomenon in which a portion of the metal layer, that is, a residual film CE2a is not removed and remains in the valley-shaped concave portion V formed between a 2-1 electrode CE2-1 and a 2-2 electrode CE2-2 can occur.

Further, referring to FIG. 12, the fourth organic insulating layer 115d can be disposed on the substrate 110 in the display region AA. The third organic insulating layer 115c can be disposed under the fourth organic insulating layer 115d. The 1-4 connection line (121d in FIG. 7) can be disposed between the third organic insulating layer 115c and the fourth organic insulating layer 115d. Here, since the first and second organic insulating layers 115a and 115b and the 1-1 to 1-4 connection lines 121a to 121d have been described with reference to FIG. 7, descriptions thereof will be omitted herein.

The plurality of banks BNK spaced apart from each other can be disposed on the fourth organic insulating layer 115d in the display region AA. Further, the plurality of first electrodes CE1 can be disposed on the plurality of banks BNK. The plurality of light-emitting elements ED1 and ED2 can be disposed on the first electrodes CE1. Here, the plurality of light-emitting elements ED1 and ED2 can be electrically connected to the first electrodes CE1 through the solder pattern SDP.

The second electrodes CE2-1 and CE2-2 can be disposed on the plurality of light-emitting elements ED1 and ED2, the plurality of banks BNK, and the first optical layer 117a. Here, the 2-1 electrode CE2-1 and the 2-2 electrode CE2-2 can be disposed spaced apart from each other in a separated state. When the 2-1 electrode CE2-1 and the 2-2 electrode CE2-2 are in contact with each other, a phenomenon such as wave mura can occur.

Accordingly, in the 2-1 electrode CE2-1 and the 2-2 electrode CE2-2 in the display region AA, there can be the possibility that a short circuit occurs between the 2-1 electrode CE2-1 and the 2-2 electrode CE2-2 due to the residual film CE2a remaining in the concave portion V formed at the upper end of the boundary region between the first optical layer 117a and the second optical layer 117b.

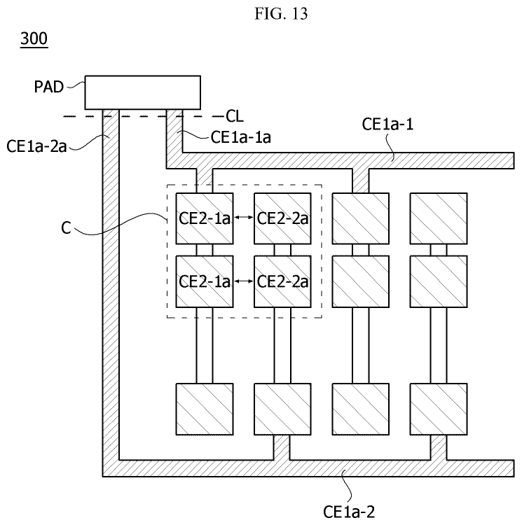

In the present disclosure, in order to detect whether a short circuit occurs between the 2-1 electrode CE2-1 and the 2-2 electrode CE2-2 in the display region AA, by measuring the resistance between a 2-1 dummy electrode CE2-1a and a 2-2 dummy electrode CE2-2a (FIG. 13) provided in a test pattern (TEG) 300 in the dummy region DA and having the same structure as the 2-1 electrode CE2-1 and the 2-2 electrode CE2-2 in the display region AA to monitor whether a short circuit occurs therebetween, there is possibility that whether a short circuit occurs between the 2-1 electrode CE2-1 and the 2-2 electrode CE2-2 in the display region AA can be detected in advance.

Accordingly, in the display region AA, since the residual film CE2a remains in the concave portion V, a phenomenon in which the 2-1 electrode CE2-1 and the 2-2 electrode CE2-2, which should be separated from each other, are short-circuited can occur. Thus, due to the residual film CE2a remaining in the concave portion V formed at the upper end of the boundary region of the first optical layer 117a and the second optical layer 117b in the display region AA, the measured resistance value decreases when a short circuit occurs between the 2-1 electrode CE2-1 and the 2-2 electrode CE2-2. Accordingly, as a defect occurs in the display device, a wave mura error can be detected.

Accordingly, in the present disclosure, as only a resistance value is measured by a probe station without actually lighting a plurality of dummy light-emitting elements ED1a and ED2a disposed in the test pattern 300 by disposing a separate test pattern 300 in the dummy region DA, whether a short circuit occurs between adjacent second electrodes CE2-1 and CE2-2 in the display region AA of the display device can be detected in advance.

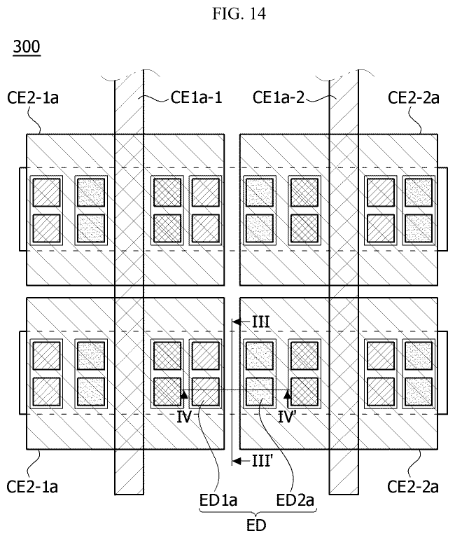

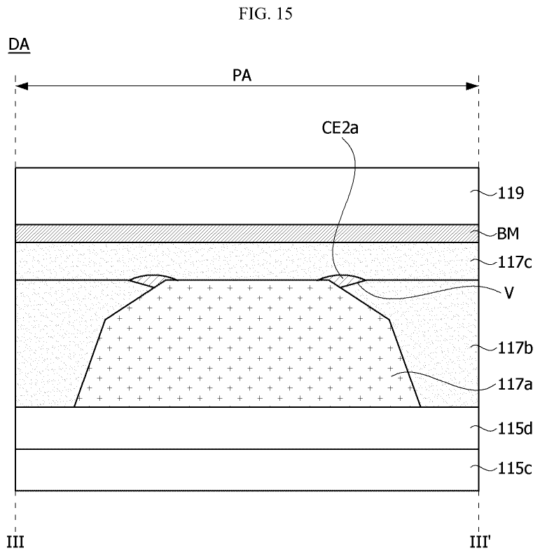

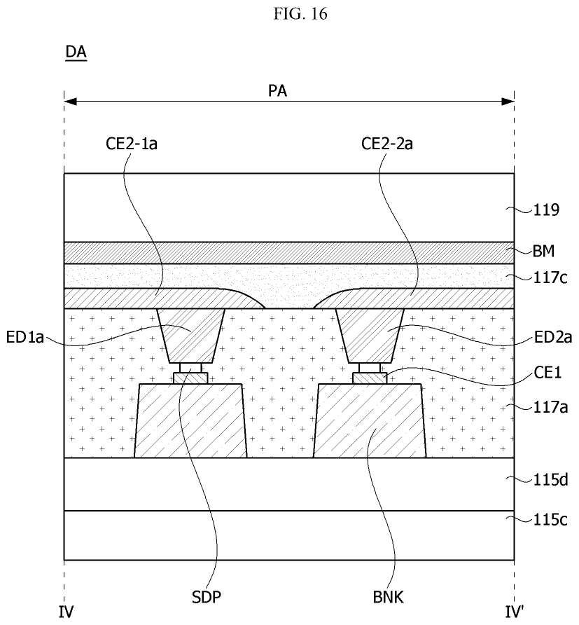

FIG. 13 is an enlarged plan view of a TEG structure of the dummy region in the display device according to the embodiments of the present disclosure. FIG. 14 is an enlarged plan view of portion C in FIG. 13. FIG. 15 is a cross-sectional view taken along line III-III′ in FIG. 14. FIG. 16 is a cross-sectional view taken along line IV-IV′ in FIG. 14.

Referring to FIG. 13, the test pattern 300 can be disposed on the substrate (110 in FIG. 7) disposed in the dummy region DA located outside the display region AA. Since the test pattern 300 is formed in the dummy region DA, and thus the metal layer deposited to form a cathode electrode, that is, the second electrode CE2 is not etched during the patterning process and the residual film CE2a remains in the valley-shaped concave portion V formed at the upper portion of the boundary region of the first and second optical layers 117a and 117b, whether a short circuit occurs between the second electrodes CE2-1 and CE2-2 which are disposed adjacent to and spaced apart from each other in the same row of the display region AA can be detected in advance.

Referring to FIGS. 13 to 16, the test pattern 300 can include a plurality of 1-1 and 1-2 dummy electrode lines CE1a-1 and CE1a-2 (also referred to as first dummy electrode lines) not connected to each other, a plurality of dummy light-emitting elements EDa, e.g., first and second dummy light-emitting elements ED1a and ED2a, disposed to face each other on the 1-1 and 1-2 dummy electrode lines CE1a-1 and CE1a-2, and a 2-1 and 2-2 dummy electrodes CE2-1a and CE2-2a (also referred to as second dummy electrodes) disposed to face each other on the plurality of first and second dummy light-emitting elements ED1a and ED2a.

The test pattern 300 is not connected to the plurality of first electrodes CE1, the plurality of light-emitting elements ED, and the plurality of second electrodes CE2 provided in the display region AA.

The first and second optical layers 117a and 117b can be disposed on the side surfaces of the plurality of dummy light-emitting elements ED1a and ED2a. In the present disclosure, an example in which one 2-1 dummy electrode CE2-1a and one 2-2 dummy electrode CE2-2a are disposed for every 8 first and second dummy light-emitting elements ED1a and ED2a is described. However, the present disclosure is not limited thereto. The plurality of 1-1 and 1-2 dummy electrode lines CE1a-1 and CE1a-2, the plurality of first and second dummy light-emitting elements ED1a and ED2a, and the plurality of 2-1 and 2-2 dummy electrodes CE2-1a and CE2-2a can constitute a plurality of dummy pixels. However, the present disclosure is not limited thereto. The plurality of first and second dummy light-emitting elements ED1a and ED2a can be disposed spaced apart from each other at a certain interval in the same row or in different rows. The 2-1 and 2-2 dummy electrodes CE2-1a and CE2-2a can be disposed to be separated from each other on the plurality of first and second dummy light-emitting elements ED1a and ED2a, respectively.

Accordingly, the 2-1 and 2-2 dummy electrodes CE2-1a and CE2-2a can be disposed to be separated from each other at a certain interval in the same row or in different rows on the plurality of first and second dummy light-emitting elements ED1a and ED2a.

Here, one end CE1a-1a of the 1-1 dummy electrode line CE1a-1 and the other end CE1a-2a of the 1-2 dummy electrode line CE1a-2 are not connected to the first electrode CE1 in the display region AA. Here, a voltage can be applied to the one end CE1a-1a of the 1-1 dummy electrode line CE1a-1 and the other end CE1a-2a of the 1-2 dummy electrode line CE1a-2 of the test pattern 300 while connected to the pad electrode PE of the pad portion PAD located in the pad region PA to measure the resistance value of the 2-1 and 2-2 dummy electrodes CE2-1 and CE2-2 and detect whether a short circuit occurs in the 2-1 and 2-2 dummy electrodes CE2-1a and CE2-2a in advance, thereby monitoring whether there is a defect in the display region.

Accordingly, after measuring whether a short circuit occurs in the 2-1 and 2-2 dummy electrodes CE2-1a and CE2-2a in the dummy region DA using the test pattern 300, the one ends CE1a-1a and CE1a-2a of the 1-1 and 1-2 dummy electrode lines CE1a-1 and CE1a-2 connected to the pad electrode PE are cut from the pad electrode PE along a cutting line CL. Accordingly, in a final product structure of the display device, the test pattern 300 remains in the display device in a residual state in the dummy region DA.

Specifically, referring to FIGS. 13 to 15, the plurality of 2-1 and 2-2 dummy electrodes CE2-1a and CE2-2a disposed in the dummy region DA can be disposed to be spaced apart or separated from each other. For example, the 2-1 and 2-2 dummy electrodes CE2-1a and CE2-1a connected to the pixels PX in the nth row and the 2-1 and 202 dummy electrodes CE2-1a and CE2-2a connected to the pixels PX in the n+1th row can be disposed to be spaced apart or separated from each other. The 2-1 and 2-2 dummy electrodes CE2-1a and CE2-2a connected to the pixels PX in the nth row can be disposed to be spaced apart or separated from each other. The 2-1 and 2-2 dummy electrodes CE2-1a and CE2-2a connected to the pixels PX in the n+1th row can be disposed to be spaced apart or separated from each other.

In the dummy region DA, the first optical layer 117a can be disposed between the 2-1 and 2-2 dummy electrodes CE2-1a and CE2-2a disposed spaced apart from each other in the same row, and the second optical layer 117b can be disposed on the side surface of the first optical layer 117a.

Here, referring to FIG. 15, the valley-shaped concave portion V can be formed at the upper end of the boundary region of the first optical layer 117a and the second optical layer 117b in the dummy region DA. Accordingly, in a process of etching the metal layer for forming the second electrodes CE2-1 and CE2-2 in the display region AA to form the 2-1 and 2-2 dummy electrodes CE2-1a and CE2-2a on the first and second optical layers 117a and 117b, a phenomenon in which a portion of the metal layer, that is, the residual film CE2a is not removed and remains in the valley-shaped concave portion V formed between the 2-1 dummy electrode CE2-1a and the 2-2 electrode CE2-2a can occur.

The fourth organic insulating layer 115d can be disposed on the substrate 110 in the dummy region DA. The third organic insulating layer 115c can be disposed under the fourth organic insulating layer 115d. Further, the 1-4 connection line (121d in FIG. 7) can be disposed between the third organic insulating layer 115c and the fourth organic insulating layer 115d. Here, the first and second organic insulating layers 115a and 115b and the 1-1 to 1-4 connection lines 121a to 121d have been described with reference to FIG. 7, and thus descriptions thereof will be omitted herein.

The plurality of banks BNK spaced apart from each other can be disposed on the fourth organic insulating layer 115d in the dummy region DA. A plurality of 1-1 and 1-2 dummy electrode lines CE1a-1 and CE2a-2 can be disposed on the plurality of banks BNK. The plurality of first and second dummy light-emitting elements ED1a and ED2a can be disposed on the 1-1 and 1-2 dummy electrode lines CE1a-1 and CE2a-2. Here, the plurality of first and second dummy light-emitting elements ED1a and ED2a can be electrically connected to the 1-1 and 1-2 dummy electrode lines CE1a-1 and CE2a-2 through the solder pattern SDP.

The 2-1 and 2-2 dummy electrodes CE2-1a and CE2-2a can be disposed on the plurality of dummy light-emitting elements ED1a and ED2a, the plurality of banks BNK, and the first optical layer 117a. Here, the 2-1 and 2-2 dummy electrodes CE2-1a and CE2-2a can be disposed in a state of being separated from each other. When the 2-1 and 2-2 dummy electrodes CE2-1a and CE2-2a are in contact with each other, a phenomenon such as wave mura can occur. Accordingly, in the 2-1 dummy electrode CE2-1a and the 2-2 dummy electrode CE2-2a, when the residual film CE2a remains between the first optical layer 117a and the second optical layer 117b, the resistance between the 2-1 dummy electrode CE2-1a and the 2-2 dummy electrode CE2-2a can be measured using the test pattern 300 provided in the dummy region DA to monitor whether a short circuit occurs between the 2-1 dummy electrode CE2-1a and the 2-2 dummy electrode CE2-2a.

Accordingly, since the residual film CE2a remains in the concave portion V, a phenomenon in which the short circuit of the 2-1 dummy electrode CE2-1a and the 2-2 dummy electrode CE2-2a, which should be separated from each other, are short-circuited can occur. Thus, when a short circuit occurs between the 2-1 dummy electrode CE2-1a and the 2-2 dummy electrode CE2-2a due to the residual film CE2a remaining in the concave portion V, the measured resistance value decreases. Accordingly, the wave mura error can be detected.

Accordingly, in the present disclosure, as only the resistance value is measured by a probe station without actually lighting the plurality of dummy light-emitting elements, e.g., ED1a and ED2a, by disposing the structure of the test pattern 300 in the dummy region DA without connecting to the display region AA, whether a short circuit occurs between adjacent second electrodes CE2-1 and CE2-2 of the display device spaced apart from each other can be detected in advance.

Thus, according to the present disclosure, open and short circuit defects of a cathode can be monitored through resistance measurement between adjacent cathode patterns when a cathode residual film occurs by adding the TEG structure which is a test pattern for measuring whether the cathode residual film occurs in the dummy region.

According to the present disclosure, it is possible to effectively monitor whether a short circuit occurs between adjacent cathode patterns due to the occurrence of the cathode residual film when the cathode is formed in the display region through the test pattern by disposing the test pattern in the dummy region, and thus whether the display device is defective can be determined in advance.

According to the present disclosure, since it is possible to identify whether a short circuit occurs between adjacent cathode patterns due to the occurrence of the cathode residual film in advance using the test pattern, the use of the defective display device can be reduced.

According to the present disclosure, it is possible to monitor whether the cathode residual film occurs without performing a breakthrough analysis or lighting by disposing the test pattern in the dummy region inside a trimming line.

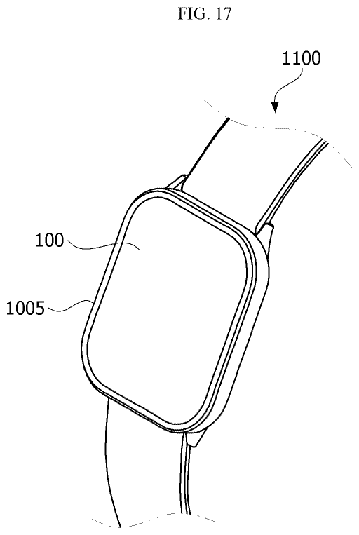

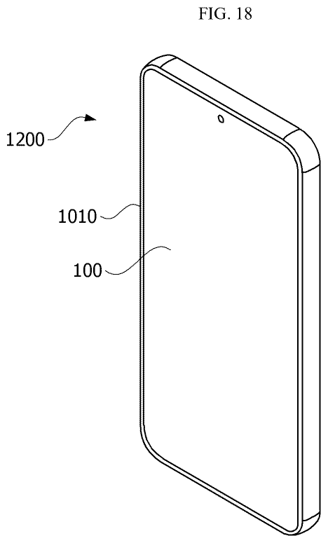

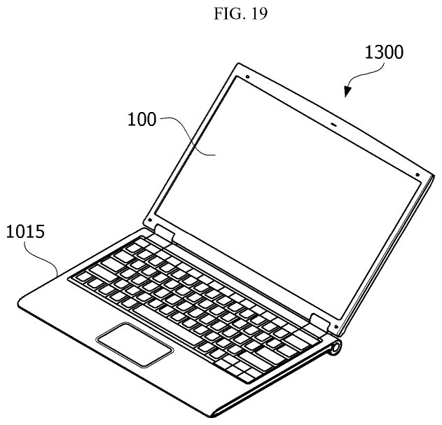

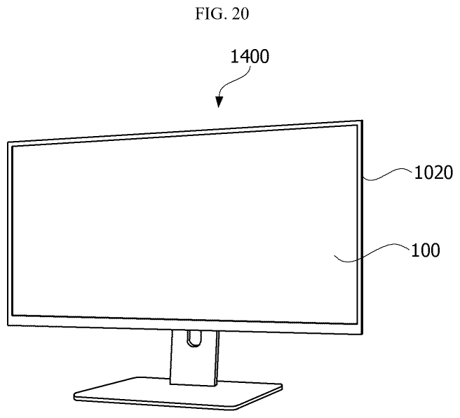

FIGS. 17 to 20 are views showing devices to which the display devices according to the embodiments of the present disclosure are applied.

Referring to FIGS. 17 to 20, the display devices 1000 according to the embodiments of the present disclosure can be included in various devices or electronic devices. For example, referring to FIGS. 17 to 20, various electronic devices can include a wearable device 1100, a mobile device 1200, a notebook 1300, and a monitor or television (TV) 1400, but the embodiments of the present disclosure are not limited thereto.

The wearable device 1100, the mobile device 1200, the notebook 1300, and the monitor or TV 1400 can respectively include case portions 1005, 1010, 1015, and 1020, and the above-described display panels 100 and display devices 1000 according to the embodiments of the present disclosure described in FIGS. 1 to 16.

For example, the display device according to the embodiments of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation device, a vehicle display device, a theater display device, a television, a wallpaper apparatus, a signage apparatus, a gaming apparatus, a notebook, a monitor, a camera, a camcorder, a home appliance, and the like.

According to the present disclosure, open and short circuit defectives of a cathode can be monitored through resistance measurement between adjacent cathode patterns when a cathode residual film occurs by adding a test element group (TEG) structure which is a test pattern for measuring whether the cathode residual film occurs in a dummy region.

According to the present disclosure, it is possible to effectively monitor whether a short circuit occurs between adjacent cathode patterns due to the occurrence of the cathode residual film when a cathode is formed in a display region through a test pattern by disposing the test pattern in the dummy region, and thus whether the display device is defective can be determined in advance.

According to the present disclosure, since it is possible to identify whether a short circuit occurs between adjacent cathode patterns due to the occurrence of the cathode residual film in advance using the TEG structure, the use of the defective display device can be reduced.

According to the present disclosure, it is possible to monitor whether a cathode residual film occurs without performing a breakthrough analysis or lighting.

The effects according to the present disclosure are not limited to the above-mentioned effects, and other effects which are not mentioned can be clearly understood by those skilled in the art from the disclosure to be described below.

The display device according to various embodiments of the present disclosure can be described as follows.

A display device according to various embodiments of the present disclosure can comprise a substrate having a display region and a non-display region outside the display region; a circuit layer disposed in the display region and the non-display region; a plurality of banks disposed on the circuit layer; a plurality of pixels each including a plurality of light-emitting elements disposed on the plurality of banks in the display region, wherein first electrodes of the plurality of pixels are connected to anode electrodes of the plurality of light-emitting elements, and second electrodes of the plurality of pixels are connected to cathode electrodes of the plurality of light-emitting elements, and adjacent second electrodes are disposed to face each other and are spaced apart from each other; a plurality of dummy pixels each including a plurality of dummy light-emitting elements disposed on the plurality of banks in the non-display region, wherein a plurality of first dummy electrode lines of the plurality of dummy pixels are connected to anode electrodes of the plurality of dummy light-emitting elements and not connected to each other, and a plurality of second dummy electrodes of the plurality of dummy pixels are connected to cathode electrodes of the plurality of dummy light-emitting elements, adjacent second dummy electrodes are disposed to face each other and are spaced apart from each other.

According to a display device of the present disclosure, the plurality of dummy light-emitting elements can be respectively disposed on the plurality of first dummy electrode lines facing each other.

According to a display device of the present disclosure, the plurality of dummy light-emitting elements may not light up.

According to a display device of the present disclosure, the plurality of first dummy electrode lines can be not connected to the first electrodes of the plurality of pixels.

According to a display device of the present disclosure, the plurality of second dummy electrodes can be not connected to the second electrodes of the plurality of pixels.

According to a display device of the present disclosure, the display device can further include an optical layer disposed on side surfaces of the plurality of light-emitting elements and the plurality of dummy light-emitting elements and on the plurality of banks.

According to a display device of the present disclosure, the optical layer can include a first optical layer that covers the side surfaces of the plurality of dummy light-emitting elements and the plurality of banks, and a second optical layer which covers a side surface of the first optical layer.

According to a display device of the present disclosure, a concave portion can be formed at an upper end of a boundary region of the first optical layer and the second optical layer.

According to a display device of the present disclosure, the optical layer can further include a third optical layer disposed on the second electrodes on the plurality of light-emitting elements and the second dummy electrodes on the plurality of dummy light-emitting elements.

According to a display device of the present disclosure, the display device can further include a black matrix disposed on the second electrodes, the second dummy electrodes, and the third optical layer, and including a plurality of through holes; and a cover layer disposed on the black matrix.

According to a display device of the present disclosure, the circuit layer can further include a pixel driving circuit disposed on the substrate and electrically connected to the plurality of light-emitting elements and a plurality of contact electrodes; and a plurality of signal lines that electrically connect the first electrodes to the pixel driving circuit.

According to a display device of the present disclosure, the plurality of second dummy electrodes can be disposed to be separated from each other at a certain interval in the same row or in different rows on the plurality of dummy light-emitting elements.

According to a display device of the present disclosure, ends of the plurality of first dummy electrode lines can be configured to be applied a voltage while connected to a pad electrode disposed in a pad region of the non-display region.

According to a display device of the present disclosure, the first optical layer can be disposed between the second dummy electrodes disposed spaced apart from each other in the same row.

A test method of a display device according to various embodiments of the present disclosure can comprise determining whether a short circuit occurs between the plurality of dummy pixels based on a resistance measurement value of the adjacent second dummy electrodes of the plurality of dummy pixels.

Although embodiments of the present disclosure have been described in more detail with reference to the accompanying drawings, the present disclosure is not necessarily limited to the embodiments, and various modifications can be carried out without departing from the technical spirit of the present disclosure.

Therefore, the embodiments disclosed in the present disclosure are not intended to limited the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A display device comprising:
a substrate having a display region and a non-display region outside the display region;
a circuit layer disposed in the display region and the non-display region;
a plurality of banks disposed on the circuit layer;
a plurality of pixels each including a plurality of light-emitting elements disposed on the plurality of banks in the display region, wherein first electrodes of the plurality of pixels are connected to anode electrodes of the plurality of light-emitting elements, and second electrodes of the plurality of pixels are connected to cathode electrodes of the plurality of light-emitting elements, and adjacent second electrodes are disposed to face each other and are spaced apart from each other; and
a plurality of dummy pixels each including a plurality of dummy light-emitting elements disposed on the plurality of banks in the non-display region,
wherein a plurality of first dummy electrode lines of the plurality of dummy pixels in the non-display region are connected to anode electrodes of the plurality of dummy light-emitting elements and are not connected to each other, and
wherein a plurality of second dummy electrodes of the plurality of dummy pixels in the non-display region are connected to cathode electrodes of the plurality of dummy light-emitting elements, and adjacent second dummy electrodes among the plurality of second dummy electrodes are disposed to face each other and are spaced apart from each other.

2. The display device of claim 1, wherein the plurality of dummy light-emitting elements are respectively disposed on the plurality of first dummy electrode lines facing each other.

3. The display device of claim 1, wherein the plurality of dummy light-emitting elements are not configured to emit light or light up.

4. The display device of claim 1, wherein the plurality of first dummy electrode lines are not connected to the first electrodes of the plurality of pixels.

5. The display device of claim 1, wherein the plurality of second dummy electrodes are not connected to the second electrodes of the plurality of pixels.

6. The display device of claim 5, further comprising an optical layer disposed on side surfaces of the plurality of light-emitting elements and the plurality of dummy light-emitting elements and on the plurality of banks.

7. The display device of claim 6, wherein the optical layer includes:
a first optical layer that covers the side surfaces of the plurality of dummy light-emitting elements and the plurality of banks, and
a second optical layer which covers a side surface of the first optical layer.

8. The display device of claim 7, wherein a concave portion is formed at an upper end of a boundary region of the first optical layer and the second optical layer.

9. The display device of claim 7, wherein the optical layer further includes:
a third optical layer disposed on the second electrodes on the plurality of light-emitting elements and the second dummy electrodes on the plurality of dummy light-emitting elements.

10. The display device of claim 9, further comprising:
a black matrix disposed on the second electrodes, the second dummy electrodes, and the third optical layer, and including a plurality of through holes; and
a cover layer disposed on the black matrix.

11. The display device of claim 1, wherein the circuit layer further includes:
a pixel driving circuit disposed on the substrate and electrically connected to the plurality of light-emitting elements and a plurality of contact electrodes; and
a plurality of signal lines that electrically connect the first electrodes of the plurality of pixels to the pixel driving circuit.

12. The display device of claim 2, wherein the plurality of second dummy electrodes are disposed to be separated from each other at a certain interval in a same row or in different rows on the plurality of dummy light-emitting elements.

13. The display device of claim 1, wherein ends of the plurality of first dummy electrode lines are configured to receive a voltage while being connected to a pad electrode disposed in a pad region of the non-display region.

14. The display device of claim 7, wherein the first optical layer is disposed between the plurality of second dummy electrodes disposed spaced apart from each other in a same row.

15. A test method for the display device of claim 1, comprising determining whether a short circuit occurs between the plurality of dummy pixels based on a resistance measurement value of the adjacent second dummy electrodes of the plurality of dummy pixels.

16. The test method for the display device of claim 15, further comprising cutting out an end portion of at least one of the plurality of first dummy electrode lines based on a result of the determining.
